(19) United States
(12) Patent Application Publication
(10) Pub. No.: US 2025/0363944 A1
(43) Pub. Date: Nov. 27, 2025

(54) DISPLAY APPARATUS AND ELECTRONIC DEVICE

(71) Applicant: Sony Group Corporation, Tokyo (JP)

(72) Inventor: Kei Kimura, Kanagawa (JP)

(21) Appl. No.: 18/865,171

(22) PCT Filed: May 15, 2023
(86) PCT No.: PCT/JP2023/018031

§ 371 Date: Nov. 12, 2024

(30) Foreign Application Priority Data
Jun. 23, 2022 (JP) 2022-100907

(51) Int. Cl. G09G 3/3233

(52) U.S. Cl. CPC G09G 3/3233; G09G 2330/021; G09G 2380/10

(57) ABSTRACT

Provided is a display apparatus including a stack structure including a light-emitting element whose luminance changes according to a supplied current, a current source transistor that is electrically connected to a current source and the light-emitting element and supplies a current corresponding to a signal voltage to the light-emitting element, a capacitor connected to a control terminal of the current source transistor, and a selection transistor that is connected to the control terminal of the current source transistor and supplies the signal voltage to the current source transistor via the capacitor, in which the stack structure includes a semiconductor substrate on which the current source transistor is provided, a wiring layer stacked on the semiconductor substrate and including the capacitor and the selection transistor formed of a thin film transistor, and the light-emitting element stacked on the wiring layer.

### FIELD

The present disclosure relates to a display apparatus and an electronic device.

### BACKGROUND

Display apparatuses in which electro luminescence (EL) elements are used as light-emitting elements have recently been developed. Such a display apparatus includes, for example, a plurality of light-emitting elements including a lower electrode, a light-emitting layer stacked on the lower electrode, and an upper electrode stacked on the light-emitting layer. The display apparatus includes a drive circuit for driving the light-emitting elements in addition to the light-emitting elements described above.

### CITATION LIST

### Patent Literature

Patent Literature 1: JP 2020-154323 A
Patent Literature 2: JP 2021-9401 A

### SUMMARY

### Technical Problem

With the miniaturization of the light-emitting element, the display apparatus is required to reduce the layout size of the drive circuit in consideration of the withstand voltage and the characteristic variation range required for various transistors included in the drive circuit. However, there is a limit to reducing the size of the transistors included in the drive circuit while satisfying the desired withstand voltage, and thus there is also a limit to reducing the layout size of the drive circuit.

The present disclosure proposes a display apparatus and an electronic device capable of reducing the layout size of the drive circuit.

### Solution to Problem

According to the present disclosure, provided is a display apparatus including a stack structure including a light-emitting element whose luminance changes according to a supplied current, a current source transistor that is electrically connected to a current source and the light-emitting element and supplies a current corresponding to a signal voltage to the light-emitting element, a capacitor connected to a control terminal of the current source transistor, and a selection transistor that is connected to the control terminal of the current source transistor and supplies the signal voltage to the current source transistor via the capacitor, in which the stack structure includes a semiconductor substrate on which the current source transistor is provided, a wiring layer stacked on the semiconductor substrate and including the capacitor and the selection transistor formed of a thin film transistor, and the light-emitting element stacked on the wiring layer.

According to the present disclosure, also provided is an electronic device equipped with a display apparatus, the display apparatus including a stack structure including a light-emitting element whose luminance changes according to a supplied current, a current source transistor that is electrically connected to a current source and the light-emitting element and supplies a current corresponding to a signal voltage to the light-emitting element, a capacitor connected to a control terminal of the current source transistor, and a selection transistor that is connected to the control terminal of the current source transistor and supplies the signal voltage to the current source transistor via the capacitor, in which the stack structure includes a semiconductor substrate on which the current source transistor is provided, a wiring layer stacked on the semiconductor substrate and including the capacitor and the selection transistor formed of a thin film transistor, and the light-emitting element stacked on the wiring layer.

### BRIEF DESCRIPTION OF DRAWINGS

FIG. 1 is a schematic diagram illustrating an example of an overall configuration of a display apparatus according to an embodiment of the present disclosure.

FIG. 2 is a circuit diagram illustrating an example of a pixel of the display apparatus according to the embodiment of the present disclosure.

FIG. 3 is a schematic diagram (part 1) illustrating an example of a sectional configuration of a pixel according to a first embodiment of the present disclosure.

FIG. 4 is a schematic diagram (part 1) illustrating an example of a planar configuration of the pixel according to the first embodiment of the present disclosure.

FIG. 5 is a schematic diagram (part 2) illustrating an example of a planar configuration of the pixel according to the first embodiment of the present disclosure.

FIG. 6 is a schematic diagram (part 2) illustrating an example of a sectional configuration of the pixel according to the first embodiment of the present disclosure.

FIG. 7 is a circuit diagram illustrating a modification of the pixel according to the first embodiment of the present disclosure.

FIG. 8 is a schematic diagram illustrating a modification of the sectional configuration of the pixel according to the first embodiment of the present disclosure.

FIG. 9 is a schematic diagram illustrating an example of an overall configuration of a display apparatus according to a second embodiment of the present disclosure.

FIG. 10 is a circuit diagram illustrating an example of a pixel of the display apparatus according to the second embodiment of the present disclosure.

FIG. 11 is a schematic diagram illustrating a sectional configuration of the pixel according to the second embodiment of the present disclosure.

FIG. 12 is a schematic diagram (part 1) illustrating an example of a planar configuration of the pixel according to the second embodiment of the present disclosure.

FIG. 13 is a schematic diagram (part 2) illustrating an example of the planar configuration of the pixel according to the second embodiment of the present disclosure.

FIG. 14 is a schematic diagram (part 3) illustrating an example of the planar configuration of the pixel according to the second embodiment of the present disclosure.

FIG. 15 is a circuit diagram (part 1) illustrating an example of a pixel of a display apparatus 10 according to a third embodiment of the present disclosure.

FIG. 16 is a circuit diagram (part 2) illustrating an example of the pixel of the display apparatus 10 according to the third embodiment of the present disclosure.

FIG. 17 is a circuit diagram (part 3) illustrating an example of the pixel of the display apparatus 10 according to the third embodiment of the present disclosure.

FIG. 18A is a sectional view (part 1) for describing a method for producing a pixel according to a fourth embodiment of the present disclosure.

FIG. 18B is a sectional view (part 2) for describing the method for producing the pixel according to the fourth embodiment of the present disclosure.

FIG. 18C is a sectional view (part 3) for describing the method for producing the pixel according to the fourth embodiment of the present disclosure.

FIG. 18D is a sectional view (part 4) for describing the method for producing the pixel according to the fourth embodiment of the present disclosure.

FIG. 18E is a sectional view (part 5) for describing the method for producing the pixel according to the fourth embodiment of the present disclosure.

FIG. 18F is a schematic diagram (part 6) for describing the method for producing the pixel according to the fourth embodiment of the present disclosure.

FIG. 18G is a schematic diagram (part 7) for describing the method for producing the pixel according to the fourth embodiment of the present disclosure.

FIG. 18H is a schematic diagram (part 8) for describing the method for producing the pixel according to the fourth embodiment of the present disclosure.

FIG. 19A is a front view illustrating an example of an external appearance of a digital still camera.

FIG. 19B is a rear view illustrating an example of an external appearance of the digital still camera.

FIG. 20 is an external view of a head mounted display.

FIG. 21 is an external view of a see-through head mounted display.

FIG. 22 is an external view of a television apparatus.

FIG. 23 is an external view of a smartphone.

FIG. 24A is a diagram (part 1) illustrating an internal configuration of an automobile.

FIG. 24B is a diagram (part 2) illustrating an internal configuration of the automobile.

### DESCRIPTION OF EMBODIMENTS

Hereinafter, preferred embodiments of the present disclosure will be described in detail with reference to the accompanying drawings. In the present specification and the drawings, components having substantially the same functional configuration are denoted by the same reference signs, and redundant description is omitted. In the present specification and the drawings, a plurality of components having substantially the same or similar functional configuration may be distinguished by attaching different alphabets after the same reference signs. When it is not particularly necessary to distinguish each of the plurality of components having substantially the same or similar functional configuration, only the same reference sign is assigned.

The drawings referred to in the following description are drawings for describing an embodiment of the present disclosure and promoting understanding thereof, and shapes, dimensions, ratios, and the like illustrated in the drawings may be different from actual ones for the sake of clarity. The display apparatuses illustrated in the drawings may be appropriately modified in design in consideration of the following description and known technologies.

In the following description, “electrically connecting” means connecting a plurality of elements directly or indirectly via another element.

In the following description, “sharing” means that one element (for example, a diffusion region or the like) is used in common among other elements different from each other (for example, transistors and the like).

The description will be given in the following order.
1. Display apparatus according to embodiment of present disclosure
1.1 Display apparatus
1.2 Pixel
2. Background to creation of embodiment of present disclosure
3. First Embodiment
3.1 Detailed structure
3.2 Modification
4. Second Embodiment
4.1 Display apparatus
4.2 Pixel
4.3 Stack structure
5. Third Embodiment
6. Fourth Embodiment
7. Conclusion
8. Application Example
9. Supplement

### 1. DISPLAY APPARATUS ACCORDING TO EMBODIMENT OF PRESENT DISCLOSURE

### 1.1 Display Apparatus

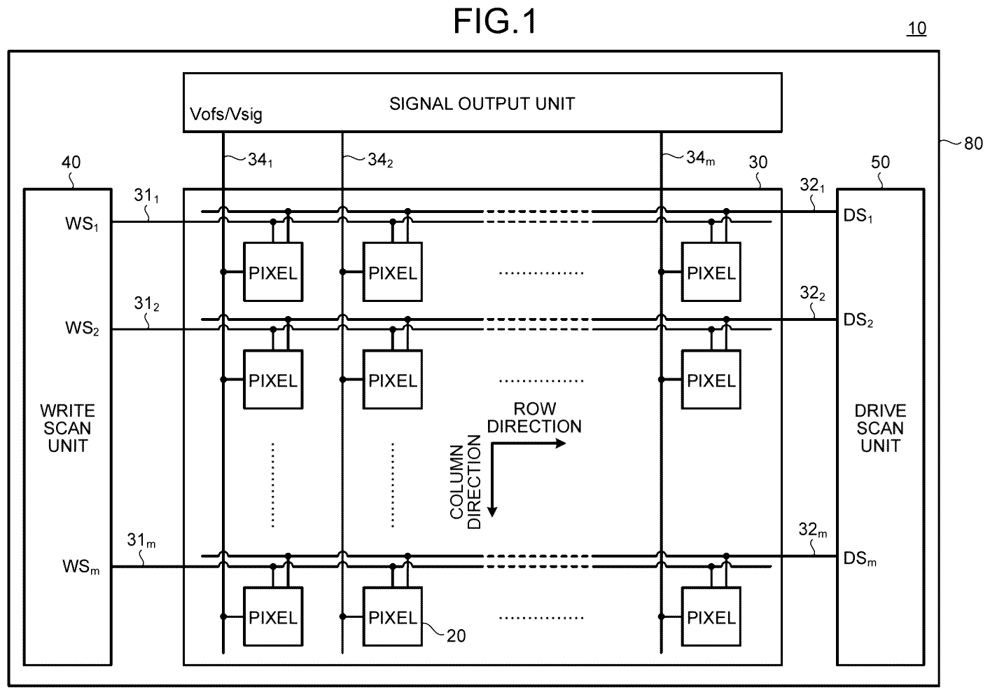

An example of an overall configuration of a display apparatus 10 according to an embodiment of the present disclosure used as a display apparatus or a lighting apparatus will be described with reference to FIG. 1. FIG. 1 is a schematic diagram illustrating an example of an overall configuration of the display apparatus 10 according to an embodiment of the present disclosure.

The display apparatus 10 is, for example, an apparatus in which light-emitting elements such as organic light emitting diodes (OLED) or micro-OLEDs are arrayed. Such a display apparatus 10 can be applied to, for example, a display apparatus for virtual reality (VR), mixed reality (MR), or augmented reality (AR), an electronic view finder (EVF), a small projector, or the like.

In an embodiment of the present disclosure, the light-emitting element may be a self-light-emitting element and may be a current-driven electro-optical element. Examples of the current-driven electro-optical element include an inorganic EL element, an LED element, and a semiconductor laser element in addition to the OLED. An organic EL display apparatus using the OLED as the light-emitting element has the following features. Specifically, in the organic EL display apparatus, since the OLED is a self-light-emitting element, the organic EL display apparatus has high visibility of an image as compared with a liquid crystal display apparatus that is the same flat type display apparatus, and moreover, it does not require a lighting member such as a backlight, and thus it is easy to reduce the weight and thickness. Further, since the response speed of the OLED is as very high as several microseconds, no afterimage occurs in the organic EL display apparatus during moving image display.

Here, as an example, a case of an active-matrix-type organic EL display apparatus using, as a light-emitting element, for example, an OLED that is a current-driven light-emitting element whose light emission luminance changes according to a value of a current flowing through the device will be described. Hereinafter, the “active-matrix-type organic EL display apparatus” is simply referred to as a “display apparatus”.

As illustrated in FIG. 1, the display apparatus 10 includes a pixel array unit 30 in which a plurality of pixels 20 including a light-emitting element are two-dimensionally disposed in a matrix, and a drive circuit unit disposed around the pixel array unit 30. The drive circuit unit includes, for example, a write scan unit 40, a drive scan unit 50, and a signal output unit 70 mounted on the same display panel 80 where the pixel array unit 30 is mounted, and drives each pixel 20 of the pixel array unit 30.

Here, when the display apparatus 10 is compatible with color display, one pixel (unit pixel/pixel) serving as a unit for forming a color image includes a plurality of subpixels. At this time, each of the subpixels corresponds to the pixel 20 in FIG. 1. More specifically, in the display apparatus 10 compatible with color display, one pixel 20 may include, for example, three subpixels of a subpixel that emits red light, a subpixel that emits green light, and a subpixel that emits blue light, and may include, for example, one, two, or more subpixels, without particular limitation. One pixel 20 is not limited to, for example, a combination of subpixels of three primary colors of red, green, and blue, and one pixel 20 may be configured by further adding subpixels of one color or a plurality of colors to the subpixels of three primary colors. More specifically, in the display apparatus 10, for example, one pixel 20 can be configured by adding a subpixel that emits white light to improve luminance, or one pixel 20 can be configured by adding at least one subpixel that emits complementary color light to expand a color reproduction range.

In the pixel array unit 30, a scan line 31 (31₁ to 31ₘ) and a drive line 32 (32₁ to 32ₘ) are wired for each pixel row along the row direction (the array direction/the horizontal direction of the pixels 20 of the pixel row) with respect to the array of the pixels 20 of m rows and n columns. Further, a signal line 34 (34₁ to 34ₙ) is wired for each pixel column along the column direction (the array direction/vertical direction of the pixels 20 of the pixel column) with respect to the array of the pixels 20 of m rows and n columns.

Each of the scan lines 31₁ to 31ₘ is electrically connected to an output end of a corresponding row of the write scan unit 40. Each of the drive lines 32₁ to 32ₘ is electrically connected to an output end of a corresponding row of the drive scan unit 50. Each of the signal lines 34₁ to 34ₙ is electrically connected to an output end of a corresponding column of the signal output unit 70.

The write scan unit 40 includes a shift register circuit and the like. When writing the signal voltage of a video signal to each pixel 20 of the pixel array unit 30, the write scan unit 40 sequentially supplies a write scan signal WS (WS₁ to WSₘ) to the scan line 31 (31₁ to 31ₘ), and thus each pixel 20 of the pixel array unit 30 can be sequentially scanned row by row.

Similarly to the write scan unit 40, the drive scan unit 50 includes a shift register circuit and the like. The drive scan unit 50 can control light emission/non-light emission (extinction) of the pixel 20 by supplying a light emission control signal DS (DS₁ to DSₘ) to the drive line 32 (32₁ to 32ₘ) in synchronization with the line sequential scanning with the write scan unit 40. In an embodiment of the present disclosure, the display apparatus 10 does not have to be provided with the drive scan unit 50 capable of controlling light emission/non-light emission (extinction) of the pixel 20.

The signal output unit 70 selectively outputs a signal voltage (hereinafter, simply referred to as “signal voltage”) Vsig of a video signal corresponding to luminance information supplied from a signal supply source (not illustrated) and a reference voltage Vofs. Here, the reference voltage Vofs is a voltage corresponding to a voltage serving as a reference of the signal voltage Vsig of the video signal or a voltage in the vicinity thereof.

The signal voltage Vsig/the reference voltage Vofs alternatively output from the signal output unit 70 is written to each pixel 20 of the pixel array unit 30 via the signal line 34 (34₁ to 34ₙ) in units of pixel rows selected by the line sequential scanning with the write scan unit 40. That is, the signal output unit 70 can write the signal voltage Vsig in units of pixel rows (lines).

### 1.2 Pixel

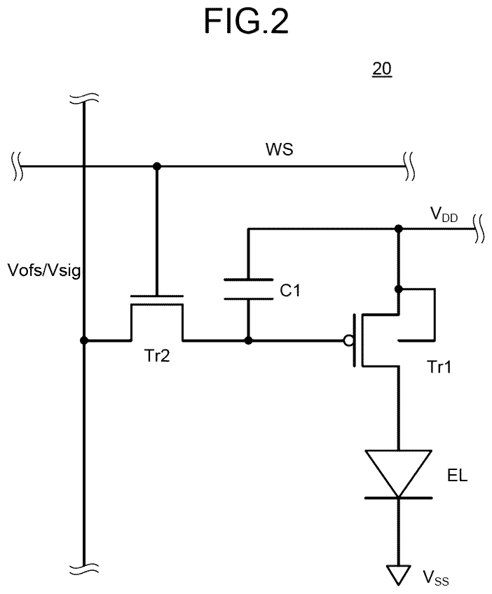

Next, a circuit configuration of the pixel (pixel circuit) 20 of the display apparatus 10 according to an embodiment of the present disclosure illustrated in FIG. 1 will be described. FIG. 2 is a circuit diagram illustrating an example of the pixel 20 of the display apparatus 10 according to an embodiment of the present disclosure. The circuit configuration illustrated in FIG. 2 corresponds to the pixel 20 of the display apparatus 10 in a case where the drive scan unit 50 capable of controlling light emission/non-light emission (extinction) of the pixel 20 is not provided.

In an embodiment of the present disclosure, as illustrated in FIG. 2, the pixel 20 includes a light-emitting element EL and a drive circuit that drives the light-emitting element EL. The light-emitting element EL is an example of a current-driven electro-optical element in which the light emission luminance changes according to the value of the current flowing through the device, and is made of, for example, an OLED. The cathode of the light-emitting element EL is electrically connected to, for example, a node V_{SS} for producing a current.

The drive circuit includes a drive transistor Tr1, a write transistor Tr2, and a capacitor C1. The anode of the light-emitting element EL is electrically connected to the drive transistor Tr1, and can emit light when a current flows through the drive transistor Tr1. The drive transistor Tr1 and the write transistor Tr2 are, for example, field effect transistors (FETs). More specifically, the drive transistor Tr1 is formed of a P-channel transistor, and the write transistor Tr2 is formed of an N-channel transistor.

Specifically, as illustrated in FIG. 2, the source and the drain of the write transistor Tr2 are electrically connected to the signal line (Vsig) and the gate (control terminal) of the drive transistor Tr1, respectively, and the gate of the write transistor Tr2 is electrically connected to the scan line (WS). The write transistor Tr2 can write in the gate node of the drive transistor Tr1 by sampling the signal voltage Vsig supplied from the signal output unit 70. The expression “write” here means that a signal voltage is applied to the gate node, and the potential of the gate node is held at a potential based on the signal voltage.

The source and the drain of the drive transistor Tr1 are electrically connected to the power supply voltage V_{DD} and the anode electrode of the light-emitting element EL, respectively. The drive transistor Tr1 can drive the light-emitting element EL by causing a drive current corresponding to a holding voltage of the capacitor C1 described later to flow through the light-emitting element EL.

The capacitor C1 is connected between the gate and the source of the drive transistor Tr1, and it can hold the signal voltage Vsig written by sampling by the write transistor Tr2.

The circuit configuration example illustrated in FIG. 2 is an example of a circuit configuration of the pixel 20 according to an embodiment of the present disclosure, and the circuit configuration of the pixel 20 according to an embodiment of the present disclosure is not limited to the circuit configuration illustrated in FIG. 2.

### 2. BACKGROUND TO CREATION OF EMBODIMENT OF PRESENT DISCLOSURE

Next, before describing the embodiments of the present disclosure, the background to the creation of the embodiments of the present disclosure by the inventors of the present invention will be described.

With the miniaturization of the light-emitting element EL, the display apparatus 10 is required to reduce the layout size of the drive circuit in consideration of the withstand voltage and the characteristic variation range required for various transistors in the drive circuit of the pixel 20. However, there is a limit to reducing the size of the transistors included in the drive circuit while satisfying the desired withstand voltage, and thus there is also a limit to reducing the layout size of the moving circuit. In particular, when an OLED is used as the light-emitting element EL, a high voltage is applied to drive the OLED, and a high withstand voltage is required for the drive transistor Tr1, thus there is a limit to reducing the layout size of the drive transistor Tr1.

Thus, in view of such a situation, the inventors of the present disclosure have created the embodiments of the present disclosure described below. In the embodiments of the present disclosure, by configuring some transistors included in the drive circuit as thin film transistors (TFT) provided in a wiring layer stacked on a semiconductor substrate, a layout size of the drive circuit can be reduced, and eventually, the display apparatus 10 can be downsized. Hereinafter, details of such embodiments of the present disclosure will be described in order.

### 3. FIRST EMBODIMENT

### 3.1 Detailed Structure

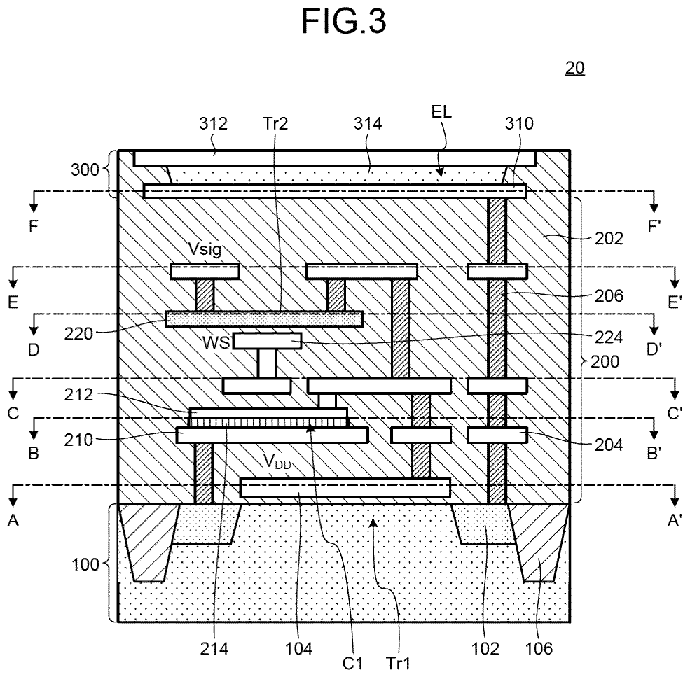

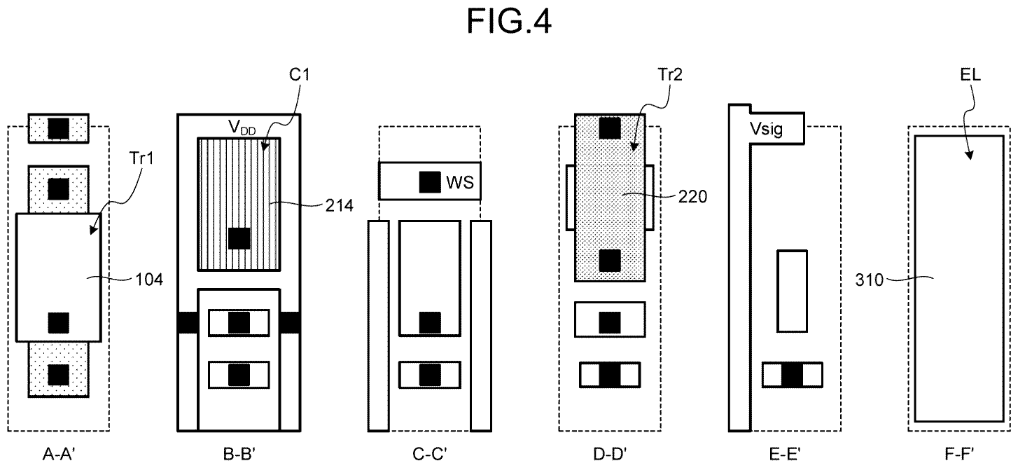

First, a detailed structure of the pixel 20 according to a first embodiment of the present disclosure will be described with reference to FIGS. 3 and 4. FIG. 3 is a schematic diagram illustrating an example of a sectional configuration of the pixel 20 according to the present embodiment, and it specifically corresponds to a section formed when a stack structure of the pixel 20 is cut along a stacking direction. FIG. 4 is a schematic diagram illustrating an example of a planar configuration of the pixel 20 according to the present embodiment, and it specifically corresponds to a section formed when the pixel 20 is cut along each line segment (line A-A′, line B-B′, line C-C′, line D-D′, line E-E′, and line F-F′) illustrated in FIG. 3. The pixel 20 having the configuration illustrated in FIGS. 3 and 4 has the circuit configuration illustrated in FIG. 2 described above.

As illustrated in FIG. 3, the pixel 20 according to the present embodiment has a stack structure including a semiconductor substrate 100 made of, for example, n-type conductivity type silicon or the like, a wiring layer 200 stacked on the semiconductor substrate 100, and a light-emitting element EL provided on the wiring layer 200. As described above, the light-emitting element EL is a current-driven electro-optical element in which the light emission luminance changes according to the value of the current flowing through the device. In the present embodiment, the semiconductor substrate 100 and the wiring layer 200 include a drive circuit that drives the light-emitting element EL. Further, the wiring layer 200 includes an insulating film 202 (formed of a silicon oxide film (SiO₂), a silicon nitride film (Si₃N₄), or the like, for example), a wiring line 204 (formed of a metal film of tungsten (W) or the like, for example), and a via 206 (formed of a metal film of tungsten or the like, for example) in addition to the elements described below.

As described with reference to FIG. 2, the drive circuit includes the drive transistor (current source transistor) Tr1, the write transistor (selection transistor) Tr2, and the capacitor C1. Hereinafter, a stack structure of the pixel 20 will be described, but description will be started from the semiconductor substrate 100 located on the bottom of FIG. 3.

The drive transistor Tr1 is a field effect transistor provided on the semiconductor substrate 100, and is specifically a P-channel transistor. Specifically, as illustrated in FIG. 3, the drive transistor Tr1 includes a gate electrode 104 provided on a region having an n-type conductivity type functioning as a channel of the drive transistor Tr1 provided in the semiconductor substrate 100, via the insulating film 202 (see the section A-A′ in FIG. 4). Further, the drive transistor Tr1 is provided in the semiconductor substrate 100 so as to sandwich the region having an n-type conductivity type functioning as a channel, and has a source/drain including a diffusion region 102 containing an impurity having a p-type conductivity type. In the present embodiment, providing the drive transistor Tr1 on the semiconductor substrate 100 in this manner makes it possible to stabilize the characteristics of the drive transistor Tr1 and to obtain a transistor having a high withstand voltage. In the present embodiment, the drive transistor Tr1 may be an N-channel transistor although details will be described later.

The source and the drain of the drive transistor Tr1 are electrically connected to the wiring line 204 connected to the power supply (V_{DD}) provided in the wiring layer 200 and an anode electrode 310 of the light-emitting element EL, respectively, by the via 206 penetrating the wiring layer 200. Further, the gate electrode 104 of the drive transistor Tr1 is electrically connected to the electrode 210 of the capacitor C1 described later and the source or the drain of the write transistor Tr2 by the via 206.

Further, the drive transistor Tr1 is separated from other elements by a shallow trench isolation (STI) 106 provided in the semiconductor substrate 100.

As illustrated in FIG. 3, the capacitor C1 is provided in the wiring layer 200 stacked above the drive transistor Tr1. Specifically, the capacitor C1 has a metal-insulator-metal (MIM) structure including a pair of electrodes (metal films) 210 and 212 sandwiching an insulating film 214 from up-down directions along the stacking direction of the stack structure (see the section B-B′ in FIG. 4). In the present embodiment, the insulating film 214 may be formed of, for example, a silicon nitride film, or may be formed of an oxide film or the like containing at least one element selected from the group consisting of silicon (Si), hafnium (Hf), zirconia (Zr), tantalum (Ta), and yttrium (Y), such as a silicon oxide film or a hafnium oxide film (HfO₂).

Further, one electrode 210 of the capacitor C1 is electrically connected to the source or the drain of the drive transistor Tr1 described above via the via 206. The other electrode 212 of the capacitor C1 is electrically connected to the source or the drain of the drive transistor Tr1 described above and the source or the drain of the write transistor Tr2 described later via the via 206.

Further, in the structure illustrated in FIG. 3, the write transistor Tr2 is provided above the capacitor C1 in the wiring layer 200. In other words, in the wiring layer 200 illustrated in FIG. 3, the capacitor C1 is provided on the semiconductor substrate 100 side, and the write transistor Tr2 is provided on the light-emitting element EL side. Although details will be described later, the present embodiment is not limited to such a structure, and the write transistor Tr2 may be provided on the semiconductor substrate 100 side, and the capacitor C1 may be provided above the write transistor Tr2C.

In the present embodiment, as illustrated in FIG. 3, the write transistor Tr2 is configured as a thin film transistor (TFT) provided in the wiring layer 200, and it can be specifically an N-channel transistor. In the present embodiment, the write transistor Tr2 may be a P-channel transistor, and details will be described later.

Specifically, the write transistor Tr2 includes a thin film semiconductor layer 220 provided in the wiring layer 200, and a gate electrode 224 in contact with the thin film semiconductor layer 220 via an insulating film 202 (see the section D-D′ in FIG. 4). The thin film semiconductor layer 220 may be formed of, for example, a silicon film, or may be formed of an oxide film or the like containing at least one element selected from the group consisting of aluminum (Al), indium (In), gallium (Ga), and zinc (Zn). More specifically, the thin film semiconductor layer 220 can be formed of polysilicon (poly-Si), indium oxide (In₂O₃), indium-gallium-zinc oxide (In and Ga are added to ZnO₄ as dopants, for example, IGZO), aluminum-zinc oxide (Al is added to ZnO as a dopant, for example, AZO), indium-zinc oxide (In is added to ZnO as a dopant, for example, IZO), or the like. In the present embodiment, since an oxide film such as IGZO has an extremely small leakage current, leakage in the write transistor Tr2 can be suppressed, and thus the thin film semiconductor layer 220 is preferably formed of an oxide film such as IGZO. With this configuration, according to the present embodiment, an increase in power consumption of the display apparatus 10 can be held down.

Further, in FIG. 3, the write transistor Tr2 is configured as a bottom gate structure in which the gate electrode 224 is located below the thin film semiconductor layer 220. However, the present embodiment is not limited to this configuration, and the write transistor Tr2 may have a top gate structure in which the gate electrode 224 is located above the thin film semiconductor layer 220 or a dual gate structure having two gate electrodes 224.

The source or the drain of the write transistor Tr2 is electrically connected to the wiring line 204 (signal voltage Vsig) provided in the wiring layer 200 by the via 206 (see the section E-E′ in FIG. 4). Further, the gate electrode 224 of the write transistor Tr2 is electrically connected to the wiring line 204 connected to the scan line (WS) by the via 206 (see the section C-C′ in FIG. 4).

As illustrated in FIG. 3, the light-emitting element EL is provided above the wiring layer 200. Specifically, the light-emitting element EL mainly includes an anode electrode 310 (see the section F-F′ in FIG. 4) provided on the wiring layer 200, a light-emitting layer 314 that is stacked on the anode electrode 310 and emits light, and a cathode electrode 312 that is stacked on the light-emitting layer 314 and transmits light from the light-emitting layer 314.

The anode electrode 310 may also have a function as a reflection layer, and it is preferably formed of a metal film having as high a reflectance as possible and a large work function to enhance light extraction efficiency. Examples of such a metal film include a metal film containing at least one of a simple substance and an alloy of metal elements such as chromium (Cr), gold (Au), platinum (Pt), nickel (Ni), copper (Cu), molybdenum (Mo), titanium (Ti), tantalum (Ta), aluminum, magnesium (Mg), iron (Fe), tungsten, and silver (Ag).

The light-emitting layer 314 provided on the anode electrode 310 is made of an organic material or an inorganic material, and it is, for example, a layer capable of emitting white light. The light-emitting layer 314 may include a hole injection layer (not illustrated) and a hole transport layer (not illustrated) provided adjacent to the anode electrode 310, and an electron transport layer (not illustrated) provided adjacent to the cathode electrode 312. In other words, the light-emitting layer 314 can have a structure in which a hole injection layer, a hole transport layer, the light-emitting layer 314, and an electron transport layer (not illustrated) are stacked from the anode electrode 310 side. The hole injection layer functions as a layer for enhancing hole injection efficiency into the light-emitting layer 314, and the layer also functions as a buffer layer for suppressing leakage. The hole transport layer functions as a layer that enhances hole transport efficiency to the light-emitting layer 314. In the light-emitting layer 314, generation of an electric field causes recombination of electrons and holes, which can generate light. The electron transport layer functions as a layer that increases electron transport efficiency to the light-emitting layer 314. Further, the light-emitting layer 314 may have an electron injection layer (not illustrated) between the electron transport layer and the cathode electrode 312. The electron injection layer functions as a layer that enhances electron injection efficiency. In the present embodiment, the configuration of the light-emitting layer 314 is not limited to the above-described configuration, and layers other than the hole injection layer and the light-emitting layer 314 can be provided as necessary.

In the present embodiment, the light-emitting layer 314 is not limited to a layer that emits white light, and the layer may be a layer that emits red light (for example, visible light having a wavelength of about 640 nm to 770 nm), blue light (for example, visible light having a wavelength of about 430 nm to 490 nm), or green light (for example, visible light having a wavelength of about 490 nm to 550 nm).

In addition, the cathode electrode 312 provided on the light-emitting layer 314 is a transparent electrode having transparency to light generated in the light-emitting layer 314, and in the following description, the transparent electrode also includes a semi-transparent electrode. The cathode electrode 312 can be formed of a metal film, an oxide film, or the like containing at least one of a simple substance and an alloy of metal elements such as aluminum, magnesium, calcium (Ca), sodium (Na), silver, indium, and zinc.

In this manner, in the present embodiment, the drive transistor Tr1 included in the drive circuit is provided in the semiconductor substrate 100, and the write transistor Tr2 is provided as a thin film transistor (TFT) in the wiring layer 200 stacked on the semiconductor substrate 100. With this configuration, according to the present embodiment, the layout size of the drive circuit can be reduced, and eventually, the display apparatus 10 can be downsized.

In the present embodiment, by forming the thin film semiconductor layer 220 of the write transistor Tr2, which is a thin film transistor (TFT), with an oxide film such as IGZO, leakage in the write transistor Tr2 can be suppressed, and as a result, an increase in power consumption of the display apparatus 10 can be suppressed.

In the present embodiment, the pixel 20 is not limited to the configuration illustrated in FIGS. 3 and 4, and for example, it may have a configuration as described below.

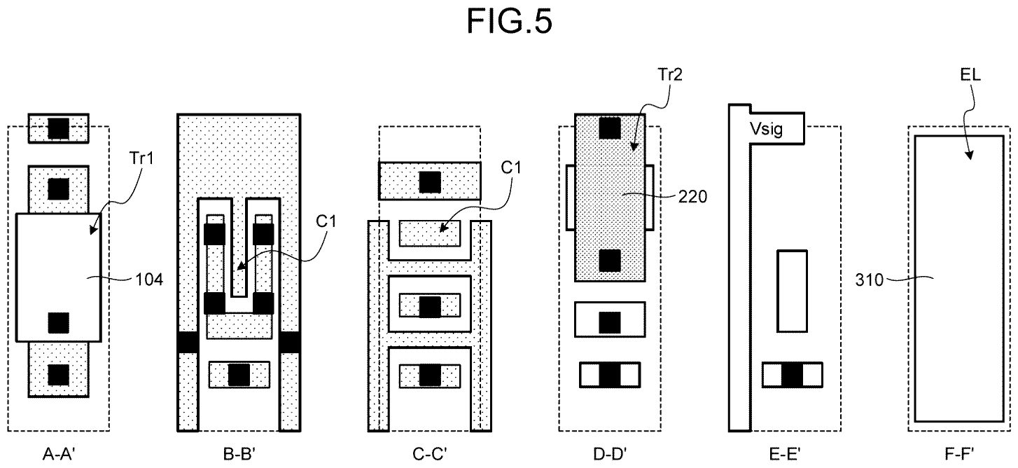

For example, in the present embodiment, the capacitor C1 is not limited to the MIM structure including the pair of electrodes 210 and 212 sandwiching the insulating film 214 from up-down directions along the stacking direction of the stack structure. For example, as illustrated in the section B-B′ and the section C-C′ in FIG. 5 which are schematic diagrams illustrating an example of a planar configuration of the pixel 20 according to the present embodiment, the capacitor C1 may have a MIM structure (or Metal-Oxide-Metal: MOM structure) including a pair of electrodes sandwiching an insulating film (oxide film) from a planar direction perpendicular to the stacking direction of the stack structure. In other words, the capacitor C1 may include a pair of electrodes provided on the same plane and facing each other with an insulating film interposed therebetween. By doing so, in the present embodiment, the number of layers stacked along the stacking direction constituting the capacitor C1 can be reduced, and thus, the pixel 20 can be thinned. FIG. 5 corresponds to a section formed when the pixel 20 is cut at each line segment (line A-A′, line B-B′, line C-C′, line D-D′, line E-E′, and line F-F′) illustrated in FIG. 3. The pixel 20 having the configuration illustrated in FIG. 5 has the circuit configuration illustrated in FIG. 2 described above.

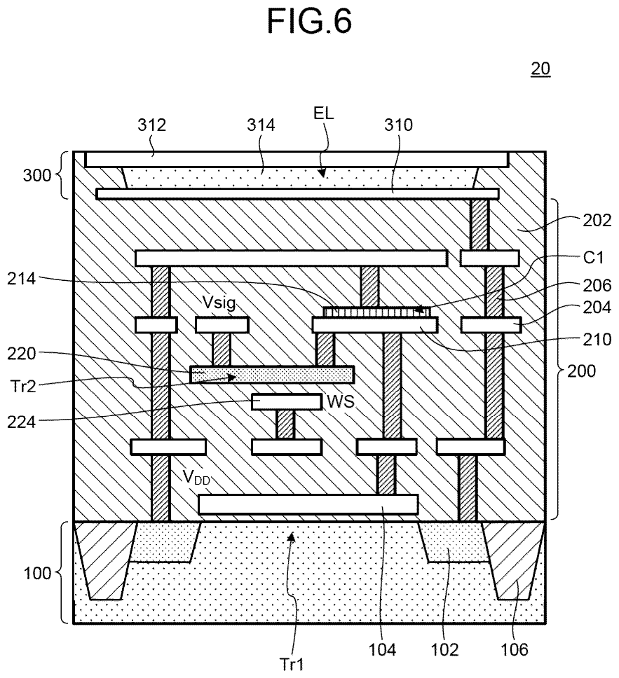

For example, in the present embodiment, as illustrated in FIG. 6 which is a schematic diagram illustrating an example of a sectional configuration of the pixel 20 according to the present embodiment, the write transistor Tr2 may be provided on the semiconductor substrate 100 side, and the capacitor C1 may be provided above the write transistor Tr2C. FIG. 6 corresponds to a section formed when the stack structure of the pixel 20 is cut along the stacking direction.

### 3.2 Modification

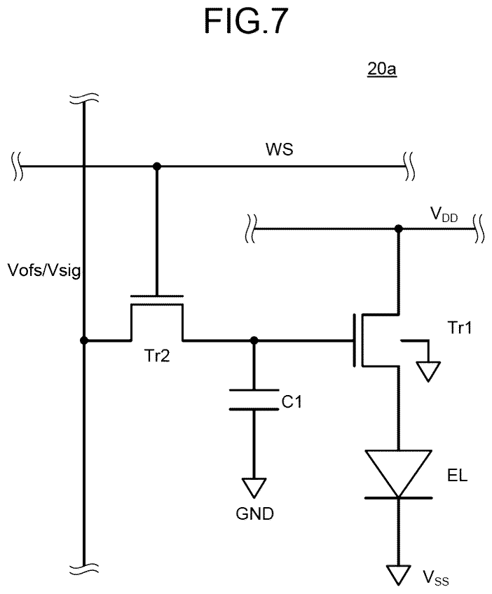

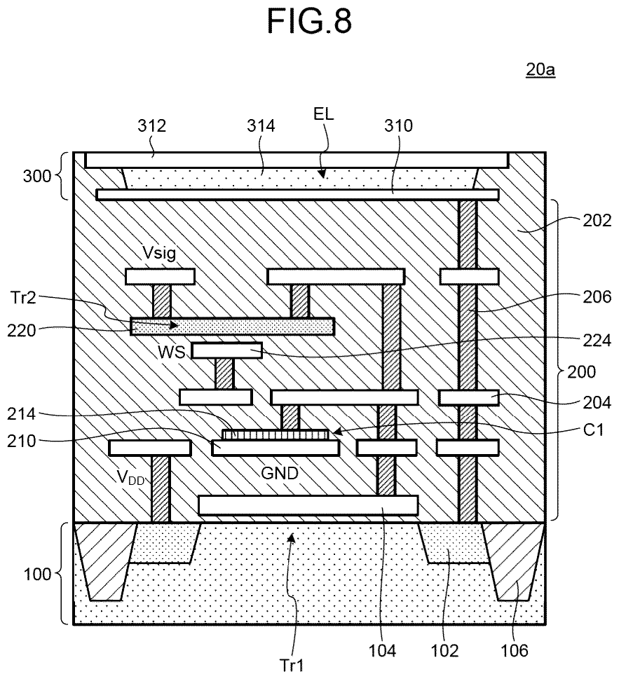

In the present embodiment, as described above, the drive transistor Tr1 may be an N-channel transistor. Hereinafter, such a modification will be described with reference to FIGS. 7 and 8. FIG. 7 is a circuit diagram illustrating a modification of a pixel 20a of the present embodiment, and FIG. 8 is a schematic diagram illustrating a modification of a sectional configuration of the pixel 20a according to the present embodiment. Specifically, FIG. 8 corresponds to a section formed when a stack structure of the pixel 20a is cut along the stacking direction.

When the drive transistor Tr1 is an N-channel transistor, the circuit configuration of the pixel 20a can be a source follower configuration (drain grounded) as illustrated in FIG. 7. Specifically, the drain and the source of the drive transistor Tr1 are electrically connected to the power supply voltage V_{DD} and the anode electrode of the light-emitting element EL, respectively. The source and the drain of the write transistor Tr2 are electrically connected to the signal line (Vsig) and the gate (control terminal) of the drive transistor Tr1, respectively, and the gate of the write transistor Tr2 is electrically connected to the scan line (WS). Further, the capacitor C1 is connected between the gate of the drive transistor Tr1 and the ground (GND).

In such a case, a sectional configuration of the pixel 20a has a configuration as illustrated in FIG. 8. Specifically, the source and the drain of the drive transistor Tr1 are electrically connected to the wiring line 204 connected to the power supply (V_{DD}) provided in the wiring layer 200 and the anode electrode 310 of the light-emitting element EL, respectively, by the via 206. Further, the gate electrode 104 of the drive transistor Tr1 is electrically connected to one electrode (not illustrated) of the capacitor C1 described later and the source or the drain of the write transistor Tr2 by the via 206. One electrode 210 of the capacitor C1 is electrically connected to the wiring line 204 connected to the ground line (GND) by the via 206.

As described above, also in the present modification, the drive transistor Tr1 included in the drive circuit is provided in the semiconductor substrate 100, and the write transistor Tr2 is provided as a thin film transistor (TFT) in the wiring layer 200 stacked on the semiconductor substrate 100. With this configuration, according to the modification, the layout size of the drive circuit can be reduced, and eventually, the display apparatus 10 can be downsized.

### 4. SECOND EMBODIMENT

### 4.1 Display Apparatus

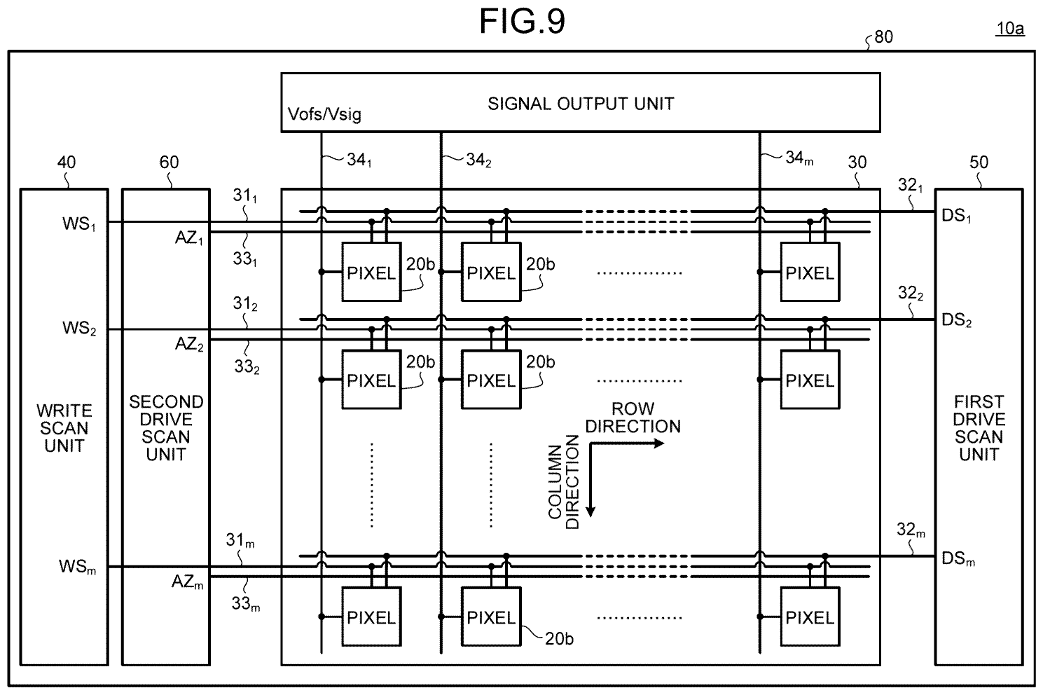

In the display apparatus 10 according to the first embodiment of the present disclosure described above, by switching the drive transistor Tr1 to off, current supply to the light-emitting element EL is cut off, and as a result, light emission of the light-emitting element EL is suppressed, and black gray scale can be displayed. However, when the drive transistor Tr1 is switched to the off state, a current leaks between the source and the drain of the drive transistor Tr1, and the contrast at the time of black gradation display may be reduced. Thus, to avoid a decrease in contrast at the time of black gradation display, the inventors of the present invention have studied the following display apparatus 10a. Hereinafter, a configuration of such a display apparatus 10a will be described with reference to FIG. 9. FIG. 9 is a schematic diagram illustrating an example of an overall configuration of the display apparatus 10a according to the present embodiment.

As illustrated in FIG. 9, the display apparatus 10a includes a pixel array unit 30 in which a plurality of pixels 20 including a light-emitting element EL are two-dimensionally disposed in a matrix, and a drive circuit unit disposed around the pixel array unit 30. In the same manner as in the display apparatus 10a described above, the drive circuit unit includes, for example, a write scan unit 40 and a signal output unit 70 mounted on the same display panel 80 where the pixel array unit 30 is mounted, and the drive circuit unit further includes a first drive scan unit 50 and a second drive scan unit 60 unlike the display apparatus 10a. In the drive unit of the display apparatus 10a according to the present embodiment, the first drive scan unit 50 corresponds to the drive scan unit 50 in the drive unit of the display apparatus 10.

The drive unit of the display apparatus 10a according to the present embodiment is different from the drive unit of the display apparatus 10 in that the drive unit includes the second drive scan unit 60, and a second drive line 33 (33₁ to 33ₘ) is wired for each pixel row along the row direction. Each of the second drive lines 33₁ to 33ₘ is connected to an output end of a corresponding row of the second drive scan unit 60.

Similarly to the write scan unit 40, the second drive scan unit 60 includes a shift register circuit and the like. The second drive scan unit 60 supplies a drive signal AZ (AZ₁ to AZₘ) to the second drive line 33 (33₁ to 33ₘ) in synchronization with the line sequential scanning by the write scan unit 40, and thus the pixel 20 can be controlled not to emit light in a non-light-emitting period.

### 4.2 Pixel

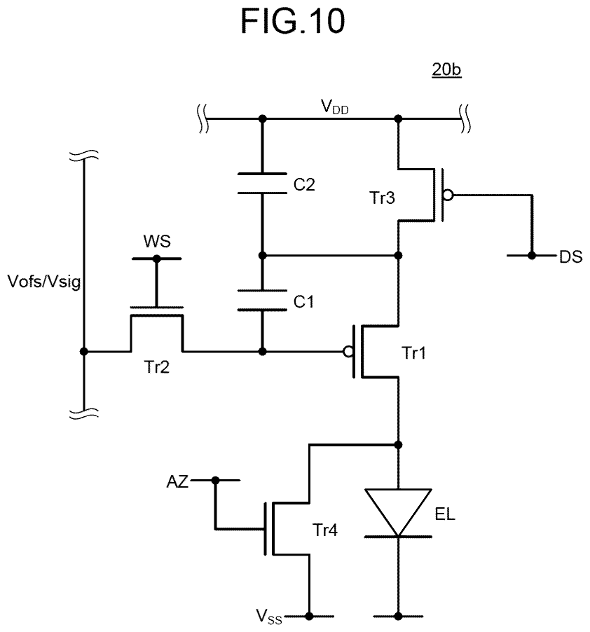

Next, a pixel 20b of the display apparatus 10a according to the present embodiment illustrated in FIG. 9 will be described. FIG. 10 is a circuit diagram illustrating an example of the pixel 20b of the display apparatus 10a according to the present embodiment. Description of points common to the pixel 20 according to the first embodiment described above is omitted here.

In the embodiments of the present disclosure as well, as illustrated in FIG. 10, the pixel 20b includes a light-emitting element EL and a drive circuit that drives a light-emitting element EL. The cathode of the light-emitting element EL is electrically connected to, for example, a node V_{SS} for producing a current. The drive circuit includes the drive transistor Tr1, the write transistor Tr2, the light emission control transistor Tr3, the switching transistor Tr4, and capacitors C1 and C2. The drive transistor Tr1 and the light emission control transistor Tr3 are P-channel transistors, and the write transistor Tr2 and the switching transistor Tr4 are N-channel transistors.

In the circuit configuration illustrated in FIG. 10, the write transistor Tr2 can write to the gate node (gate electrode) of the drive transistor Tr1 by sampling the signal voltage Vsig supplied from the signal output unit 70. The light emission control transistor Tr3 is connected between the power node of the power supply voltage VOD and the source node (source electrode) of the drive transistor Tr1, and controls light emission/non-light emission of the light-emitting element EL under driving performed by the light emission control signal DS.

The switching transistor Tr4 is connected between the drain node (drain electrode) of the drive transistor Tr1 and the current discharge destination node V_{SS}, and it performs control so that the light-emitting element EL does not emit light during a non-light-emitting period of the light-emitting element EL under driving performed by the drive signal AZ. That is, when the switching transistor Tr4 is brought into a conductive state, the switching transistor Tr4 serves to form a path bypassing the light-emitting element EL (that is, a bypass is performed) so that a current is not supplied to the light-emitting element EL. By doing so, even when a current leaks between the source and the drain of the drive transistor Tr1 when the drive transistor Tr1 is switched to the off state, the switching transistor Tr4 is brought into a conductive state, and thus a current can be prevented from being supplied to the light-emitting element EL. As a result, according to the present embodiment, it is possible to suppress a decrease in contrast at the time of black gradation display.

The capacitor C1 is connected between the gate node and the source node of the drive transistor Tr1, and it holds the signal voltage Vsig written by sampling by the write transistor Tr2. The drive transistor Tr1 drives the light-emitting element EL by causing a drive current corresponding to the holding voltage of the capacitor C1 to flow through the light-emitting element EL.

The capacitor C2 is connected between the source node of the drive transistor Tr1 and a node (for example, the power node of the power supply voltage V_{DD}) of a fixed potential. The capacitor C2 has an action of suppressing fluctuation of the source voltage of the drive transistor Tr1 when the signal voltage Vsig is written and making the gate-source voltage Vgs of the drive transistor Tr1 equal to the threshold voltage Vth of the drive transistor Tr1.

The circuit configuration example illustrated in FIG. 10 is an example of a circuit configuration of the pixel 20b of the present embodiment, and the circuit configuration of the pixel 20b according to the present embodiment is not limited to the circuit configuration illustrated in FIG. 10.

### 4.3 Stack Structure

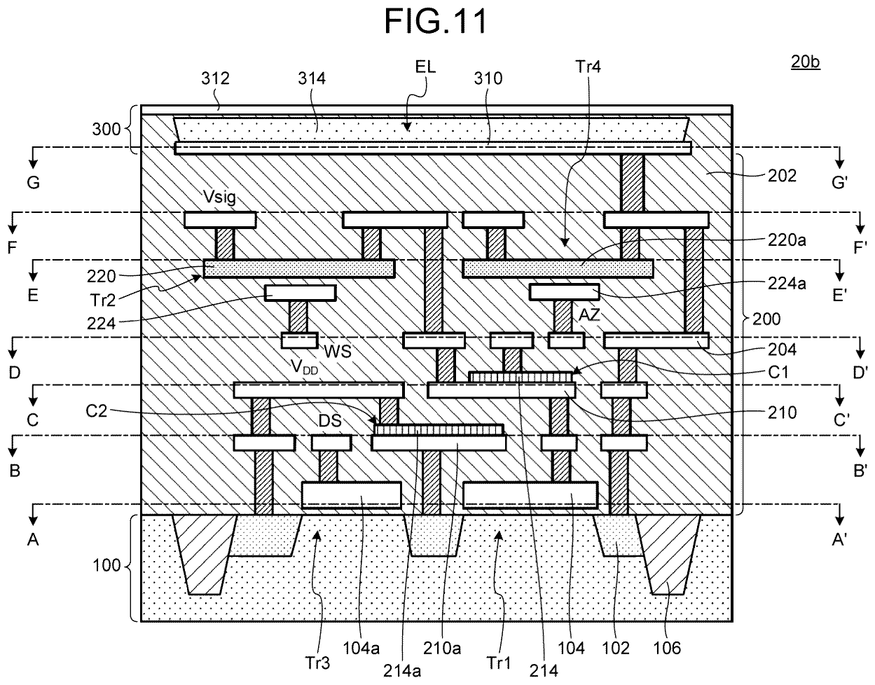

Next, a detailed structure of the pixel 20b according to the present embodiment will be described with reference to FIGS. 11 and 12. FIG. 11 is a schematic diagram illustrating a sectional configuration of the pixel 20b according to the present embodiment, and specifically, it corresponds to a section formed when the stack structure according to the pixel 20b is cut along the stacking direction. FIG. 12 is a schematic diagram illustrating an example of a planar configuration of the pixel 20b according to the present embodiment, and specifically, it corresponds to a section formed when the pixel is cut along each line segment (line A-A′, line B-B′, line C-C′, line D-D′, line E-E′, line F-F′, and line G-G′) illustrated in FIG. 11. The pixel 20b having the configuration illustrated in FIGS. 11 and 12 has the circuit configuration illustrated in FIG. 10 described above.

As illustrated in FIG. 11, the pixel 20b according to the present embodiment has a stack structure including a semiconductor substrate 100 made of, for example, n-type conductivity type silicon or the like, a wiring layer 200 stacked on the semiconductor substrate 100, and a light-emitting element EL provided on the wiring layer 200. In the present embodiment as well, the semiconductor substrate 100 and the wiring layer 200 include a drive circuit that drives the light-emitting element EL. Further, the wiring layer 200 includes an insulating film 202, a wiring line 204, and a via 206 in addition to the elements described below.

Further, as described with reference to FIG. 10, the drive circuit includes a drive transistor Tr1, a write transistor Tr2, a light emission control transistor Tr3, a switching transistor Tr4, and capacitors C1 and C2. Hereinafter, the stack structure of the pixel 20b will be described, but the description will be started from the semiconductor substrate 100 located on the bottom of FIG. 11.

Specifically, as illustrated in FIG. 11, in the same manner as in the first embodiment, the drive transistor Tr1 includes a gate electrode 104 provided on a region having an n-type conductivity type functioning as a channel of the drive transistor Tr1 provided in the semiconductor substrate 100, via an insulating film 202 (see the section A-A′ in FIG. 12). Further, the drive transistor Tr1 is provided in the semiconductor substrate 100 so as to sandwich the region having an n-type conductivity type functioning as a channel, and has a source/drain including a diffusion region 102 containing an impurity having a p-type conductivity type. In the present embodiment as well, providing the drive transistor Tr1 on the semiconductor substrate 100 in this manner makes it possible to stabilize the characteristics of the drive transistor Tr1 and to obtain a transistor having a high withstand voltage.

The source or the drain of the drive transistor Tr1 shares the diffusion region 102 provided in the semiconductor substrate 100 with the source or the drain of the light emission control transistor Tr3 provided in the semiconductor substrate 100. That is, the drive transistor Tr1 and the light emission control transistor Tr3 have a series gate structure in which one diffusion region 102 is shared by the source or the drain of one transistor and the source or the drain of the other transistor. In the present embodiment, it is preferable to select the series gate structure to suppress an increase in the layout area of the drive transistor Tr1 and the light emission control transistor Tr3, but the present embodiment is not limited to this configuration.

Further, the source and the gate of the drive transistor Tr1 are electrically connected to an electrode 210a of the capacitor C2 described later and the anode electrode 310 of the light-emitting element EL by the via 206, respectively. Further, the gate electrode 104 of the drive transistor Tr1 is electrically connected to the electrode 210 of the capacitor C1 described later and the source or the drain of the write transistor Tr2 by the via 206.

As illustrated in FIG. 11, in the same manner as in the drive transistor Tr1, the light emission control transistor Tr3 includes a gate electrode 104a provided on a region having an n-type conductivity type functioning as a channel of the light emission control transistor Tr3 provided in the semiconductor substrate 100, via an insulating film 202 (see the section A-A′ in FIG. 12). Further, the light emission control transistor Tr3 has a source/drain formed of a diffusion region 102 containing an impurity having a p-type conductivity type, the source/drain sandwiching a region having an n-type conductivity type functioning as a channel. In this manner, in the present embodiment, by providing the light emission control transistor Tr3 on the semiconductor substrate 100, it is possible to provide a transistor having a high withstand voltage with a high driving force while stabilizing the characteristics. Further, the light emission control transistor Tr3 is separated from the drive transistor Tr1 by the shallow trench isolation 106 provided in the semiconductor substrate 100.

The source or the drain of the light emission control transistor Tr3 is electrically connected to the electrode 210a of the capacitor C2 provided in the wiring layer 200 and the wiring line 204 connected to the power supply (V_{DD}) by the via 206. Further, the gate electrode 104a of the light emission control transistor Tr3 is electrically connected to the signal source of the light emission control signal DS by the via 206.

As illustrated in FIG. 11, the capacitor C2 is provided in the wiring layer 200 stacked above the drive transistor Tr1 and the light emission control transistor Tr3. Specifically, the capacitor C2 has an MIM structure including a pair of electrodes (metal films) sandwiching an insulating film 214a from up-down directions along the stacking direction of the stack structure illustrated in FIG. 11 (see the section B-B′ in FIG. 12). Further, one side of the capacitor C2 is electrically connected to the source/drain shared by the drive transistor Tr1 and the light emission control transistor Tr3 described above by the via 206. The other side of the capacitor C1 is electrically connected to the wiring line 204 connected to the power supply (V_{DD}) via the via 206.

As illustrated in FIG. 11, the capacitor C1 is provided in the wiring layer 200 stacked above the capacitor C2. Specifically, the capacitor C1 has an MIM structure including a pair of electrodes (metal films) sandwiching the insulating film 214 from up-down directions along the stacking direction of the stack structure illustrated in FIG. 11 (see the C-C′ section in FIG. 12). Further, one side of the capacitor C1 is electrically connected to the gate of the drive transistor Tr1 described above by the via 206. The other side of the capacitor C1 is electrically connected to a source/drain of the write transistor Tr2 to be described later by the via 206.

In the present embodiment, the capacitor C1 is not limited to being provided above the capacitor C2, and for example, the capacitor C1 may be provided below the capacitor C2, or may be provided at the same height, that is, in the same layer in the stack structure of the pixel 20b.

Further, in the structure illustrated in FIG. 11, the switching transistor Tr4 is provided above the capacitor C1 in the wiring layer 200. In other words, in the wiring layer 200 illustrated in FIG. 11, the capacitor C1 is provided on the semiconductor substrate 100 side, and the switching transistor Tr4 is provided on the light-emitting element EL side. The present embodiment is not limited to such a structure, and the switching transistor Tr4 may be provided on the semiconductor substrate 100 side, and the capacitor C1 and the capacitor C2 may be provided above the switching transistor Tr4.

In the present embodiment, as illustrated in FIG. 11, the switching transistor Tr4 is configured as a thin film transistor (TFT) provided in the wiring layer 200, and it can be, for example, an N-channel transistor. Specifically, the switching transistor Tr4 includes a thin film semiconductor layer 220a provided in the wiring layer 200, and a gate electrode 224a in contact with the thin film semiconductor layer 220a via the insulating film 202 (see the section E-E′ in FIG. 12). In the present embodiment, since an oxide film such as IGZO has an extremely small leak current, leakage in the switching transistor Tr4 can be suppressed, and thus the thin film semiconductor layer 220a is preferably formed of an oxide film such as IGZO. With this configuration, according to the present embodiment, an increase in power consumption of the display apparatus 10a can be suppressed. Further, when the thin film semiconductor layer 220a is formed of IGZO or the like, it is easy to form the switching transistor Tr4 as an N-channel transistor. Thus, the switching transistor Tr4 that is an N-channel transistor can stably control the cathode-anode of the light-emitting element EL to 0 V, and a current can be prevented from being supplied to the light-emitting element EL. As a result, according to the present embodiment, it is possible to suppress a decrease in contrast at the time of black gradation display.

The source or the drain of the switching transistor Tr4 is electrically connected to the anode electrode 310 of the light-emitting element EL provided on the wiring layer 200 by the via 206. Further, the gate electrode 224 of the switching transistor Tr4 is electrically connected to the wiring line 204 connected to the drive signal source (AZ) by the via 206 (see the section D-D′ in FIG. 12).

In the structure illustrated in FIG. 11, the write transistor Tr2 is provided above the capacitor C1 in the wiring layer 200. In FIG. 11, the switching transistor Tr4 and the write transistor Tr2 are provided at the same height, that is, at the same layer in the stack structure of the pixel 20b. However, in the present embodiment is not limited to this structure, and for example, the switching transistor Tr4 and the write transistor Tr2 may be provided at different heights, that is, in different layers, and may be stacked on each other in the stack structure of the pixel 20b.

Also in the present embodiment, as illustrated in FIG. 11, the write transistor Tr2 is configured as a thin film transistor (TFT) provided in the wiring layer 200, and it can be, for example, an N-channel transistor. Specifically, the write transistor Tr2 includes a thin film semiconductor layer 220 provided in the wiring layer 200, and a gate electrode 224 in contact with the thin film semiconductor layer 220 via an insulating film 202 (see the E-E′ section in FIG. 12). In the present embodiment as well, since an oxide film such as IGZO has an extremely small leakage current, leakage in the write transistor Tr2 can be suppressed, and thus the thin film semiconductor layer 220 is preferably formed of an oxide film such as IGZO. With this configuration, according to the present embodiment, an increase in power consumption of the display apparatus 10a can be suppressed.

The source or the drain of the write transistor Tr2 is electrically connected to the wiring line 204 connected to the signal line (Vsig) provided in the wiring layer 200 by the via 206. Further, the gate electrode 224 of the write transistor Tr2 is electrically connected to the wiring line 204 connected to the scan line (WS) by the via 206 (see the section F-F′ in FIG. 12).

Further, as illustrated in FIG. 11, the light-emitting element EL is provided above the wiring layer 200. Specifically, the light-emitting element EL mainly includes an anode electrode 310 (see the section G-G′ in FIG. 12) provided on the wiring layer 200, a light-emitting layer 314 that is stacked on the anode electrode 310 and emits light, and a cathode electrode 312 that is stacked on the light-emitting layer 314 and transmits light from the light-emitting layer 314.

In this manner, in the present embodiment as well, the drive transistor Tr1 included in the drive circuit and the light emission control transistor Tr3 are provided in the semiconductor substrate 100, and the write transistor Tr2 and the switching transistor Tr4 are provided as thin film transistors (TFT) in the wiring layer 200 stacked on the semiconductor substrate 100. With this configuration, according to the present embodiment, the layout size of the drive circuit can be reduced, and eventually, the display apparatus 10 can be downsized.

In addition, in the present embodiment, forming the thin film semiconductor layers 220 and 220a of the write transistor Tr2 and the switching transistor Tr4, which are thin film transistors (TFT), with an oxide film such as IGZO makes it possible to suppress leakage from the write transistor Tr2 and the switching transistor Tr4. As a result, in the present embodiment, an increase in power consumption of the display apparatus 10a can be suppressed. Further, the present embodiment, in which leakage can be suppressed, facilitates intermittent driving of the switching transistor Tr4, which also can suppress an increase in power consumption of the display apparatus 10a.

Further, according to the present embodiment, when the thin film semiconductor layer 220a of the switching transistor Tr4 is formed of IGZO or the like, it is easy to form the switching transistor Tr4 as an N-channel transistor. Thus, the switching transistor Tr4 that is an N-channel transistor can stably control the cathode-anode of the light-emitting element EL to 0 V, and a current can be prevented from being supplied to the light-emitting element EL. As a result, according to the present embodiment, it is possible to suppress a decrease in contrast at the time of black gradation display.

In the present embodiment, the pixel 20b is not limited to the configuration illustrated in FIGS. 11 and 12, and for example, it may have a configuration as described below.

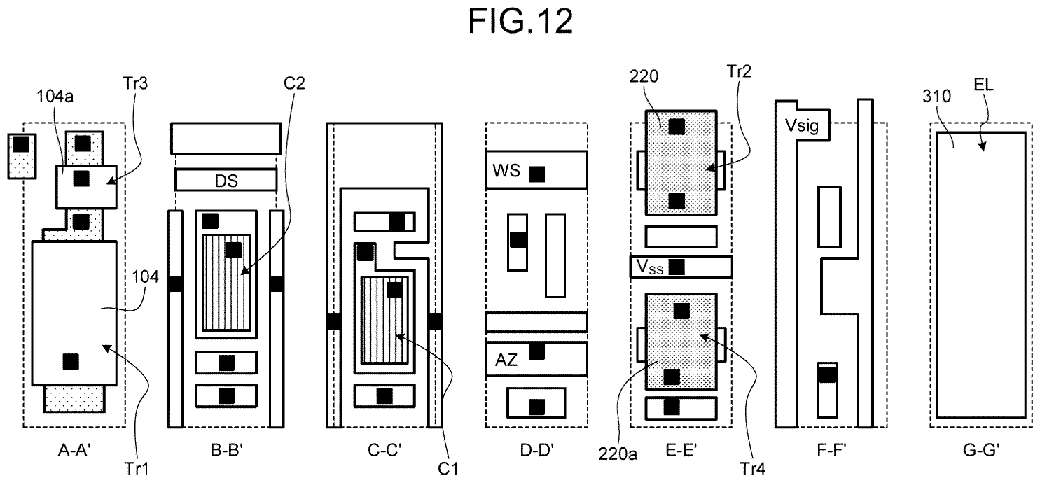

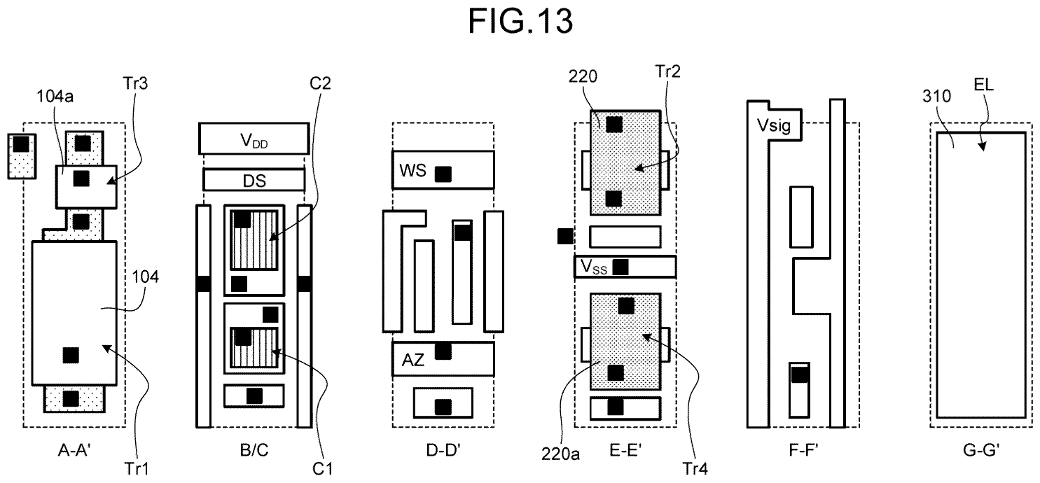

For example, in the present embodiment, as illustrated in the section B/C in FIG. 13 which is a schematic diagram illustrating an example of a planar configuration of the pixel 20b according to the present embodiment, the capacitors C1 and C2 may be provided at the same height, that is, at the same layer in the stack structure of the pixel 20b. By doing so, in the present embodiment, since the capacitors C1 and C2 can be simultaneously formed, an increase in the production step of the pixel 20b can be suppressed. FIG. 13 corresponds to a section formed when the pixel 20b is cut along each line segment (line A-A′, line D-D′, line E-E′, and line F-F′) illustrated in FIG. 11, and only the section B/C is a section present between sections obtained by cutting the pixel 20b along line B-B′ and line C-C′. The pixel 20b having the configuration illustrated in FIG. 13 has the circuit configuration illustrated in FIG. 10 described above.

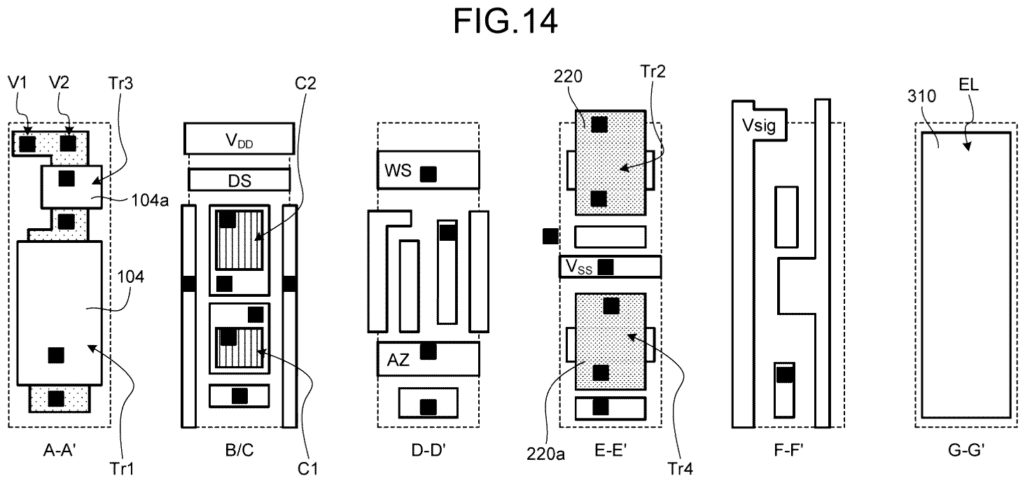

In the present embodiment, as illustrated in FIG. 14 which is a schematic diagram illustrating an example of a planar configuration of the pixel 20b according to the present embodiment, a butting contact structure in which contacts V1 and V2 having different conductivity types are disposed side by side and electrically connected via a connection electrode may be adopted. Specifically, the source contact V2 of the drive transistor Tr1 and the contact V1 of the well region of the semiconductor substrate 100 may be electrically connected via an electrode (not illustrated). This configuration makes it possible to suppress an increase in the planar layout of the pixel 20b in the present embodiment. FIG. 14 corresponds to a section formed when the pixel 20b is cut along each line segment (line A-A′, line D-D′, line E-E′, and line F-F′) illustrated in FIG. 11, and only the section B/C is a section present between sections obtained by cutting the pixel 20b along line B-B′ and line C-C′. The pixel 20b having the configuration illustrated in FIG. 14 has the circuit configuration illustrated in FIG. 10 described above.

### 5. THIRD EMBODIMENT

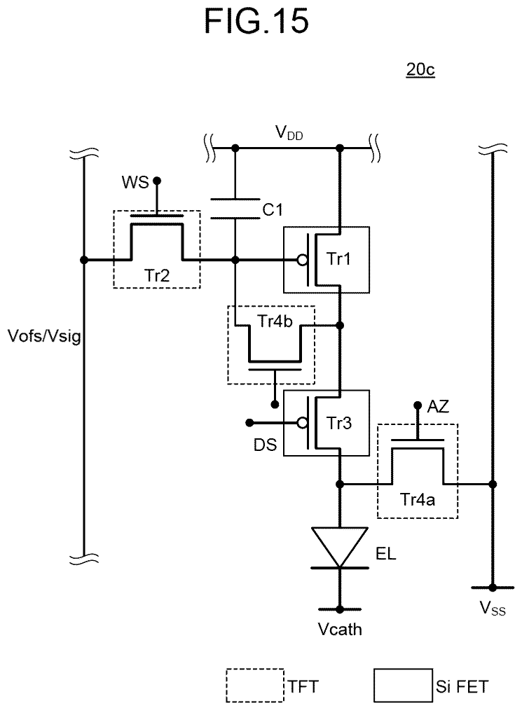

The embodiments of the present disclosure are not limited to being applied to the configuration of the pixel 20 described above, and they can be applied to the pixel 20 having various circuit configurations. As a third embodiment of the present disclosure, an application example to the pixel 20 having various circuit configurations will be described with reference to FIGS. 15 to 17. FIGS. 15 to 17 are circuit diagrams illustrating examples of pixels 20c, 20d, and 20e of the display apparatus 10 according to the present embodiment.

First, in the circuit configuration of the pixel 20c illustrated in FIG. 15, the pixel 20c includes a light-emitting element EL and a drive circuit that drives the light-emitting element EL. The drive circuit includes a drive transistor Tr1, a write transistor Tr2, a light emission control transistor Tr3, two switching transistors Tr4a and Tr4b, and a capacitor C1. The drive transistor Tr1 and the light emission control transistor Tr3 are P-channel transistors, and the write transistor Tr2 and the two switching transistors Tr4a and Tr4b are N-channel transistors.

When the embodiments of the present disclosure are applied to the circuit configuration of FIG. 15, for example, the drive transistor Tr1 and the light emission control transistor Tr3 can be Si FETs provided in the semiconductor substrate 100 made of silicon, while the write transistor Tr2 and the two switching transistors Tr4a and Tr4b can be TFTs provided in the wiring layer 200 on the semiconductor substrate 100.

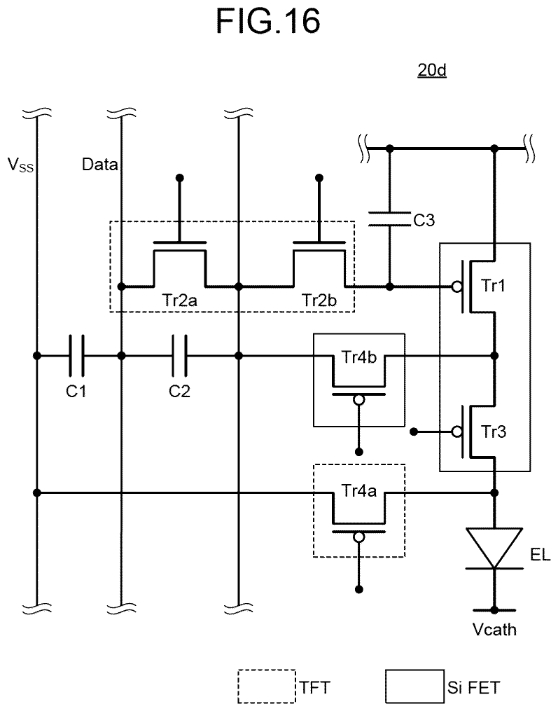

In the circuit configuration of the pixel 20d illustrated in FIG. 16, the pixel 20d includes a light-emitting element EL and a drive circuit that drives the light-emitting element EL. The drive circuit includes a drive transistor Tr1, two write transistors Tr2a and Tr2b, a light emission control transistor Tr3, two switching transistors Tr4a and Tr4b, and capacitors C1, C2, and C3. The drive transistor Tr1, the light emission control transistor Tr3, and the switching transistor Tr4b are P-channel transistors, and the two write transistors Tr2a and Tr2b and the switching transistor Tr4a are N-channel transistors.

When the embodiments of the present disclosure are applied to the circuit configuration of FIG. 16, for example, the drive transistor Tr1, the light emission control transistor Tr3, and the switching transistor Tr4b can be Si FETs provided in the semiconductor substrate 100 made of silicon, while the two write transistors Tr2a and Tr2b and the switching transistor Tr4a can be TFTs provided in the wiring layer 200 on the semiconductor substrate 100.

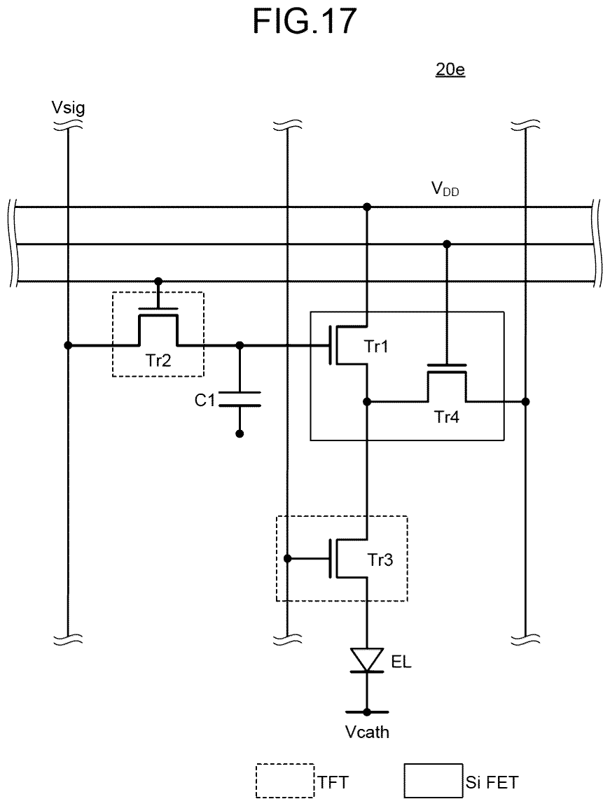

In the circuit configuration of the pixel 20e illustrated in FIG. 17, the pixel 20e includes a light-emitting element EL and a drive circuit that drives the light-emitting element EL. The drive circuit includes the drive transistor Tr1, the write transistor Tr2, the light emission control transistor Tr3, the switching transistor Tr4, and a capacitor C1. The drive transistor Tr1, the write transistor Tr2, the light emission control transistor Tr3, and the switching transistor Tr4 are N-channel transistors.

When the embodiments of the present disclosure are applied to the circuit configuration of FIG. 17, for example, the drive transistor Tr1 and the switching transistor Tr4 can be Si FETs provided in the semiconductor substrate 100 made of silicon, while the write transistor Tr2 and the light emission control transistor Tr3 can be TFTs provided in the wiring layer 200 on the semiconductor substrate 100.

In this manner, in the present embodiment, by configuring some transistors included in the drive circuit as thin film transistors (TFT) provided in a wiring layer stacked on a semiconductor substrate, a layout size of the drive circuit can be reduced, and eventually, the display apparatus 10 can be downsized.

### 6. FOURTH EMBODIMENT

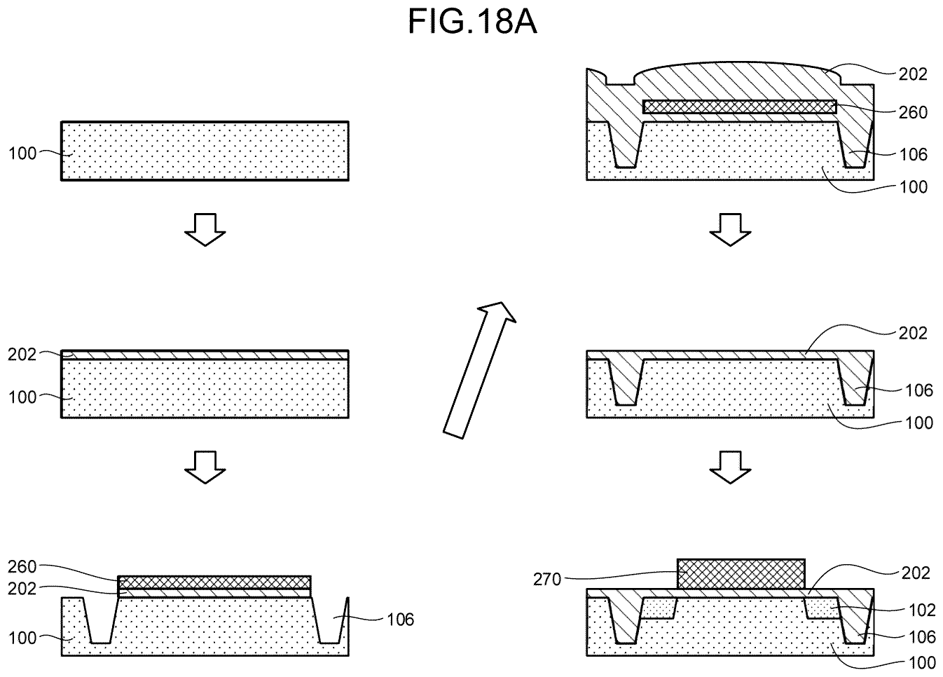

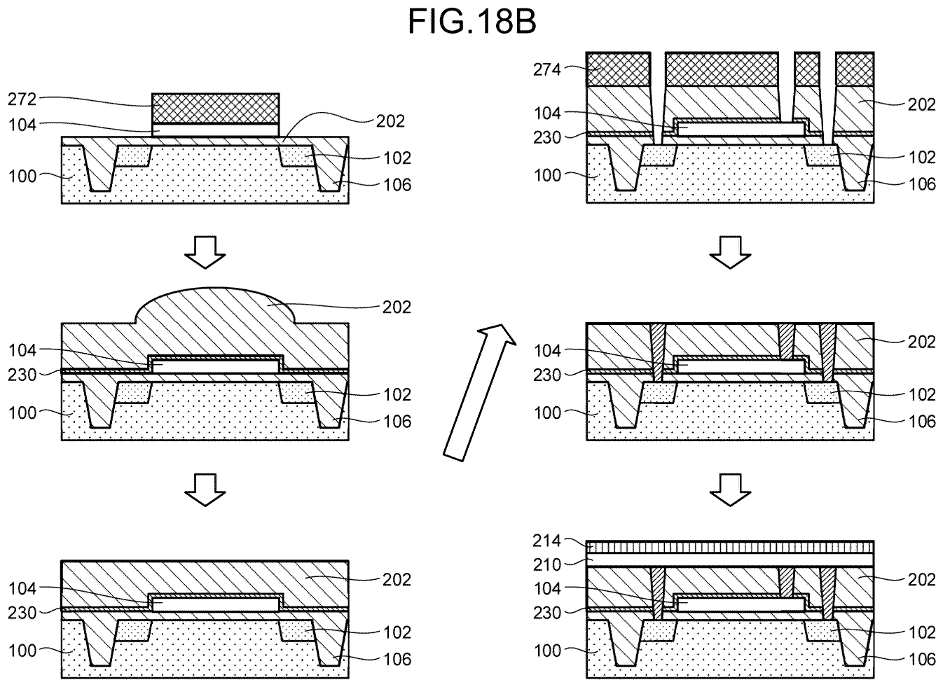

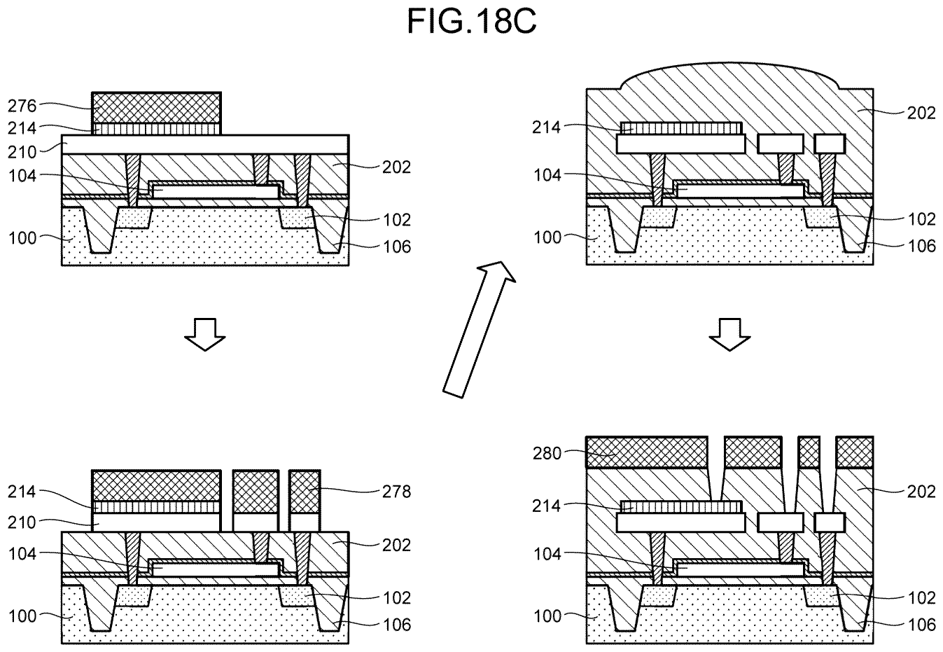

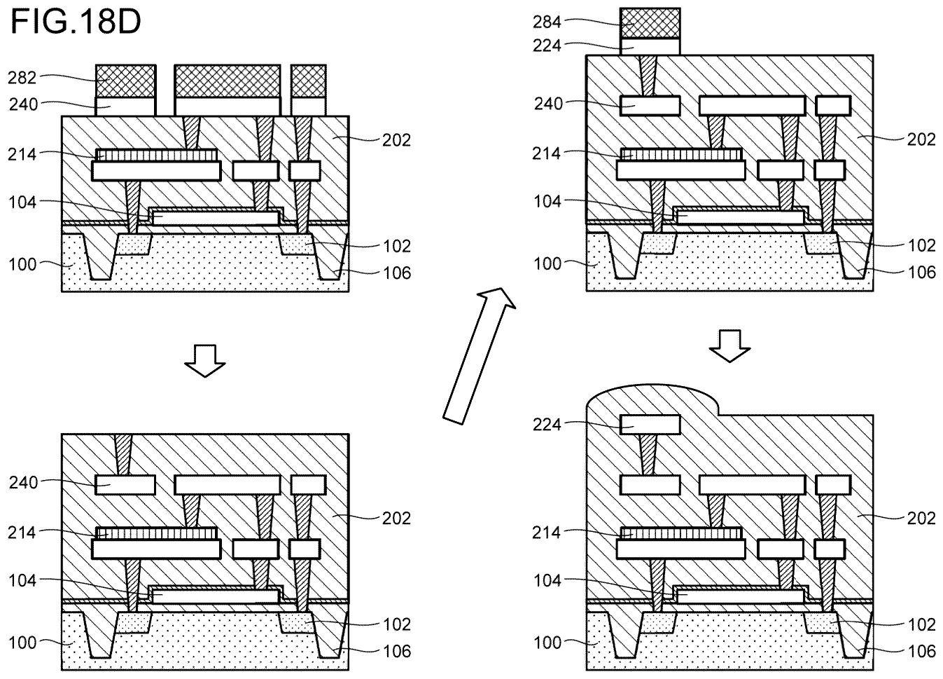

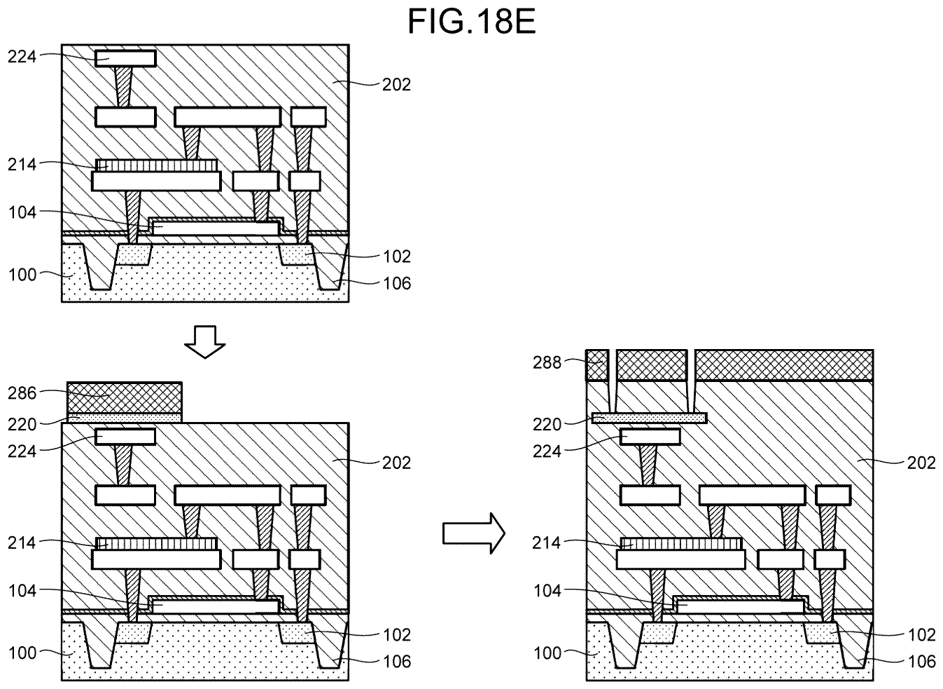

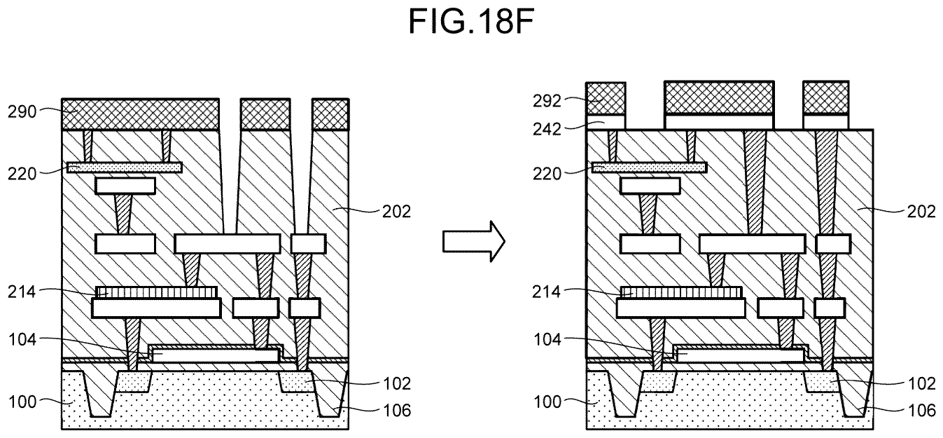

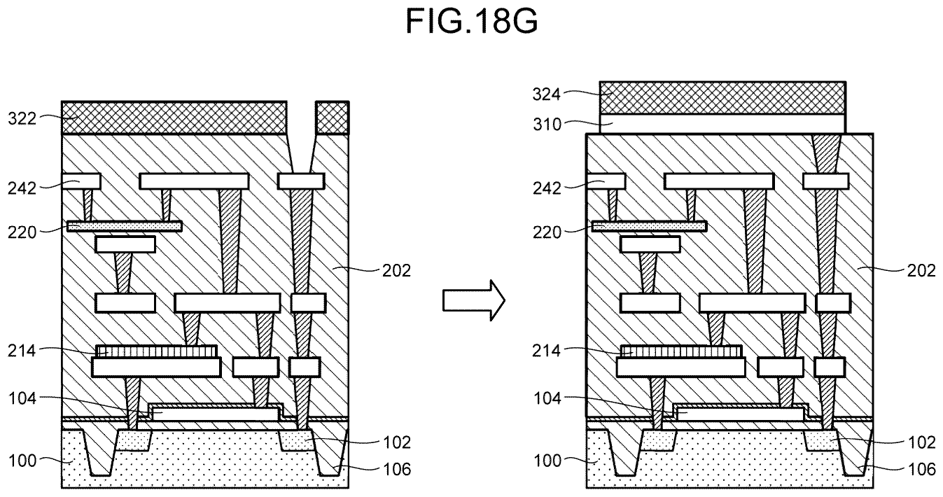

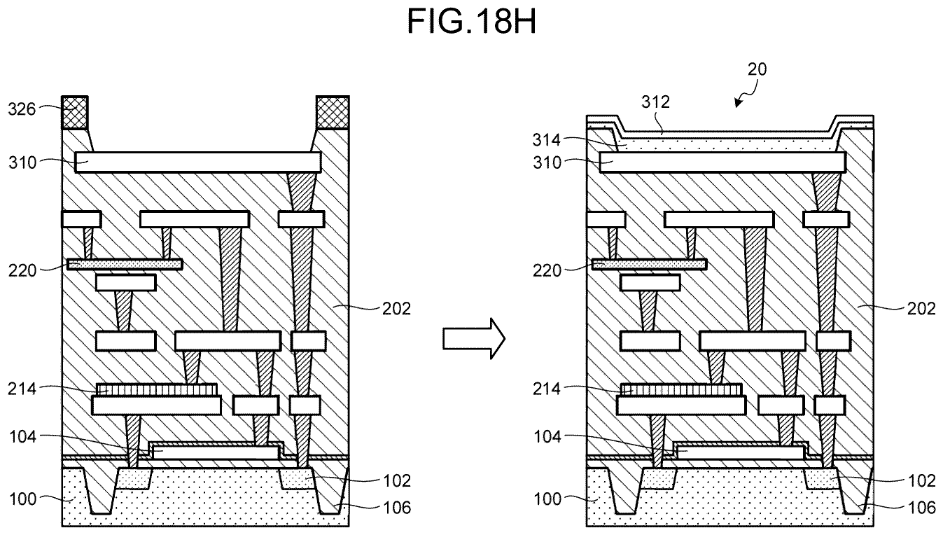

Next, an example of a method for producing the pixel 20 according to the first embodiment of the present disclosure will be described with reference to FIGS. 18A to 18H. FIGS. 18A to 18H are sectional views for describing the method for producing the pixel (pixel circuit) 20 according to the present embodiment, and they specifically correspond to the section illustrated in FIG. 3.

First, as illustrated in the upper left part of FIG. 18A, the semiconductor substrate 100 having n-type conductivity made of silicon is prepared, for example. Next, as illustrated in the second part from the top on the left side of FIG. 18A, the insulating film 202 made of, for example, a silicon oxide film (SiO₂) is formed on a surface of the semiconductor substrate 100. Further, as illustrated in the third part from the top on the left side of FIG. 18A, a mask 260 made of a silicon nitride film (Si₃N₄) is formed on the insulating film 202, and a trench to be the shallow trench isolation 106 is formed in the semiconductor substrate 100 by dry etching according to the pattern (opening) of the mask 260.

Next, as illustrated in the upper right part of FIG. 18A, the insulating film 202 made of a silicon oxide film is formed using chemical vapor deposition (CVD) in such a manner as to fill the trench. Next, as illustrated in the second part from the top on the right side of FIG. 18A, after the surface is flattened using chemical mechanical polishing (CMP), the mask 260 is removed by wet etching. Further, as illustrated in the third part from the top on the right side of FIG. 18A, a predetermined region of the semiconductor substrate 100 is covered with a mask (resist) 270, and a p-type conductive impurity is ion-implanted into the semiconductor substrate 100 to form a diffusion region 102 to be the source/drain of the drive transistor Tr.

Next, as illustrated in the upper left part of FIG. 18B, the gate electrode 104 is formed on the insulating film 202 on the semiconductor substrate 100 sandwiched between the diffusion region 102 serving as the source/drain of the drive transistor Tr. At this time, the gate electrode 104 can be patterned by forming a mask 272 on the metal film to be the gate electrode 104 and performing dry etching. As illustrated in the second part from the top on the left side of FIG. 18B, a silicon nitride film 230 serving as an interlayer insulating film and the insulating film 202 made of, for example, a silicon oxide film are stacked on the semiconductor substrate 100 using CVD. Further, as illustrated in the third part from the top on the left side of FIG. 18B, the surface of the interlayer insulating film is flattened using CMP.

Next, as illustrated in the upper right part of FIG. 18B, a mask 274 is formed on the interlayer insulating film, and dry etching is performed according to the pattern of the mask 274 to form holes. As illustrated in the second part from the top on the right side of FIG. 18B, a conductive material such as tungsten is embedded by CVD in such a manner as to fill the inside of the hole, and the upper portion is flattened using CMP. Further, as illustrated in the third part from the top on the right side of FIG. 18B, a metal film to be the electrode 210 is formed on the flattened surface by sputtering, and a film to be the insulating film 214 of the capacitor C1 is formed by sputtering or atomic layer deposition (ALD).

Next, as illustrated in the upper left part of FIG. 18C, the insulating film 214 is patterned by dry etching using a mask 276. As illustrated in the lower left part of FIG. 18C, the electrode 210 and the like are patterned by dry etching using a mask 278. As illustrated in the upper right part of FIG. 18C, the insulating film 202 made of a silicon oxide film is formed by CVD in such a manner as to cover the insulating film 214 and the like. Further, as illustrated in the lower right part of FIG. 18 C, after the insulating film 202 is flattened by CMP, a mask 280 is formed, and a hole is formed by dry etching according to the pattern of the mask 280.

Next, as illustrated in the upper left part of FIG. 18D, a conductive material is embedded by CVD in such a manner as to fill the inside of the hole, and an upper portion thereof is flattened by CMP. Further, a wiring line 240 is formed thereon by sputtering, and the wiring line 240 is patterned by dry etching using a mask 282. As illustrated in the lower left part of FIG. 18D, the insulating film 202 made of a silicon oxide film is formed by CVD, the insulating film 202 is flattened by CMP, a mask is then formed, a hole is formed by dry etching according to the pattern of the mask, a conductive material is embedded by a CVD method in such a manner as to fill the hole, and the upper portion thereof is flattened by a CMP method.

Further, as illustrated in the upper right part of FIG. 18D, a conductive material to be the gate electrode 224 of the write transistor Tr2 is formed on the insulating film 202 by CVD, and dry etching is performed using a mask 284 to pattern the gate electrode 224. Further, as illustrated in the lower right part of FIG. 18D, the insulating film 202 is formed on the gate electrode 224.

Next, as illustrated in the upper left part of FIG. 18E, after the insulating film 202 is flattened by CMP, the insulating film 202 to be the gate insulating film of the write transistor Tr2 is formed by an ALD method. As illustrated in the lower left part of FIG. 18E, the thin film semiconductor layer 220 is formed by sputtering, and the thin film semiconductor layer 220 is patterned by dry etching using a mask 286. As illustrated in the lower right part of FIG. 18E, the insulating film 202 made of a silicon oxide film is formed by CVD, the insulating film 202 is flattened by CMP, a mask 288 is then formed, and a hole is formed by dry etching according to the pattern of the mask 288.

Next, as illustrated on the left side of FIG. 18F, a conductive material is formed by CVD in such a manner as to fill the inside of the hole, and an upper portion thereof is flattened by CMP. Further, a mask 290 is formed, and a hole is formed using dry etching according to the pattern of the mask 290. Next, as illustrated on the right side of FIG. 18F, a conductive material is formed by CVD in such a manner as to fill the inside of the hole, and an upper portion thereof is flattened by CMP. Further, a wiring line 242 is formed thereon, and the wiring line 242 is patterned by dry etching using a mask 292.

Next, as illustrated on the left side of FIG. 18G, the insulating film 202 made of a silicon oxide film is formed by CVD, the surface of the insulating film 202 is flattened by CMP, a mask 322 is then formed, and a hole is formed by dry etching according to the pattern of the mask 322. Further, as illustrated on the right side of FIG. 18G, a conductive material is formed by CVD in such a manner as to fill the inside of the hole, and an upper portion thereof is flattened by CMP. Further, the electrode 310 is formed thereon, and the electrode 310 is patterned by dry etching using a mask 324.

Next, as illustrated on the left side of FIG. 18H, the insulating film 202 made of a silicon oxide film is formed by CVD, and dry etching is performed on the insulating film 202 according to the pattern of a mask 326 to form an opening that exposes a part of the electrode 310. Further, as illustrated on the right side of FIG. 18H, after the mask 326 is removed, the light-emitting layer 314 is formed on the electrode 310 by a vapor deposition method, and the electrode 312 is formed on the light-emitting layer 314.

### 7. CONCLUSION

In this manner, according to an embodiment of the present disclosure, by configuring some transistors included in the drive circuit as thin film transistors (TFT) provided in a wiring layer stacked on a semiconductor substrate, a layout size of the drive circuit can be reduced, and eventually, the display apparatus 10 can be downsized.

The technology of the present disclosure may be applied not only to the display apparatus 10 but also to a lighting apparatus or the like.

In the embodiments of the present disclosure described above, the semiconductor substrate 100 is not necessarily a silicon substrate, and it may be another substrate (for example, a silicon on insulator (SOI) substrate, a SiGe substrate, or the like).

The display apparatus 10 according to an embodiment of the present disclosure can be produced by using methods, apparatuses, and conditions used for producing a typical semiconductor device. That is, the display apparatus 10 according to the present embodiment can be produced using an existing method for producing a semiconductor device.

Examples of the above-described method include a physical vapor deposition (PVD) method, a CVD method, and an ALD method. Examples of the PVD method include a vacuum vapor deposition method, an electron beam (EB) vapor deposition method, various sputtering methods (magnetron sputtering method, radio frequency (RF)-direct current (DC) coupled bias sputtering method, electron cyclotron resonance (ECR) sputtering method, counter target sputtering method, high frequency sputtering method, and the like), an ion plating method, a laser ablation method, a molecular beam epitaxy (MBE) method, and a laser transfer method. Examples of the CVD method include a plasma CVD method, a thermal CVD method, a metal organic (MO) CVD method, and a photo CVD method. Further, other methods include electrolytic plating methods, electroless plating methods, spin coating methods; immersion methods; cast methods; micro-contact printing; drop cast methods; various printing methods such as a screen printing method, an inkjet printing method, an offset printing method, a gravure printing method, and a flexographic printing method; stamping methods; spray methods; and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendar coater method. Further, examples of a patterning method include chemical etching such as shadow mask, laser transfer, or photolithography, and physical etching using ultraviolet rays, laser, or the like. Examples of the flattening technique include a CMP method, a laser flattening method, a reflow method, and the like.

### 8. APPLICATION EXAMPLE

For example, the technology according to the present disclosure may be applied to a display unit or the like of various electronic devices. Hereinafter, an example of an electronic device to which the present technology can be applied will be described below.

### Specific Example 1

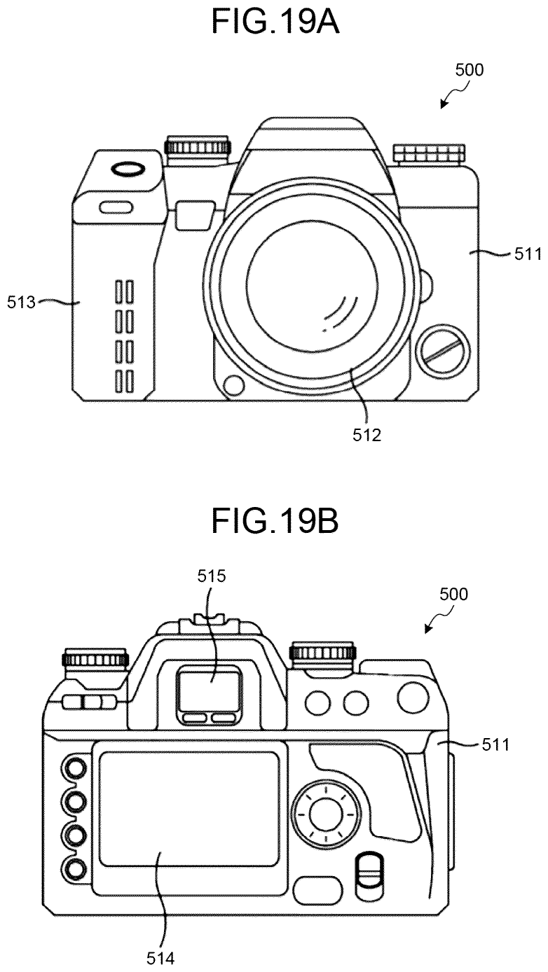

FIG. 19A is a front view illustrating an example of an external appearance of a digital still camera 500, and FIG. 19B is a rear view illustrating an example of an external appearance of the digital still camera 500. The digital still camera 500 is of a lens interchangeable single lens reflex type, the camera including an interchangeable imaging lens unit (interchangeable lens) 512 substantially at the center of the front of a camera body 511, and a grip portion 513 to be held by a photographer on the front left side.

A monitor 514 is provided at a position shifted to the left from the center of the rear surface of the camera body 511. An electronic view finder (eyepiece window) 515 is provided above the monitor 514. The photographer can visually recognize an optical image of a subject guided from the imaging lens unit 512 and determine a composition by looking into the electronic view finder 515. As the monitor 514 and the electronic view finder 515, the display apparatus 10 according to an embodiment of the present disclosure can be used.

### Specific Example 2

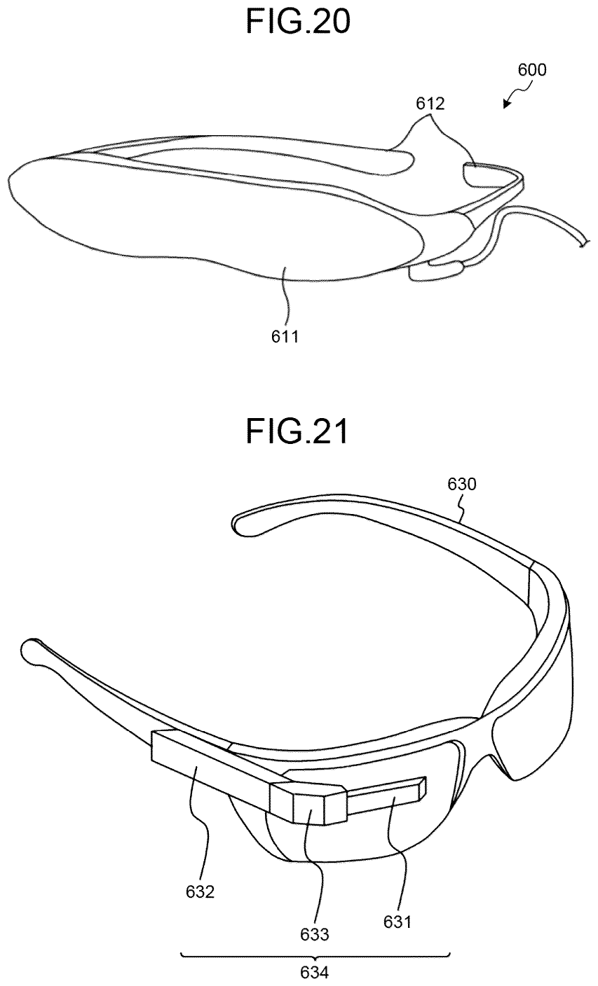

FIG. 20 is an external view of a head mounted display 600. The head mounted display 600 includes, for example, ear hooks 612 to be worn on the head of a user on both sides of an eyeglass-shaped display unit 611. The display apparatus 10 according to an embodiment of the present disclosure can be used as the display unit 611 in the head mounted display 600.

### Specific Example 3

FIG. 21 is an external view of a see-through head mounted display 634. The see-through head mounted display 634 includes a body 632, an arm 633, and a lens barrel 631.

The body 632 is connected to the arm 643 and eyeglasses 630. Specifically, an end of the body 632 in a long side direction is coupled to the arm 633, and one side surface of the body 632 is coupled to the eyeglasses 630 via a connecting member. The body 632 may be directly mounted on the head of a human body.

The body 632 incorporates a control board for controlling the operation of the see-through head mounted display 634 and a display unit. The arm 633 connects the body 632 and the lens barrel 631 and supports the lens barrel 631. Specifically, the arm 633 is coupled to an end of the body 632 and an end of the lens barrel 631 to fix the lens barrel 631. The arm 633 incorporates a signal line for communicating data related to an image provided from the body 632 to the lens barrel 631.

The lens barrel 631 projects image light provided from the body 632 via the arm 633 toward the eyes of a user wearing the see-through head mounted display 634 through eyepiece lenses. The display apparatus 10 according to an embodiment of the present disclosure can be used as the display unit of the body 632 in the see-through head mounted display 634.

### Specific Example 4

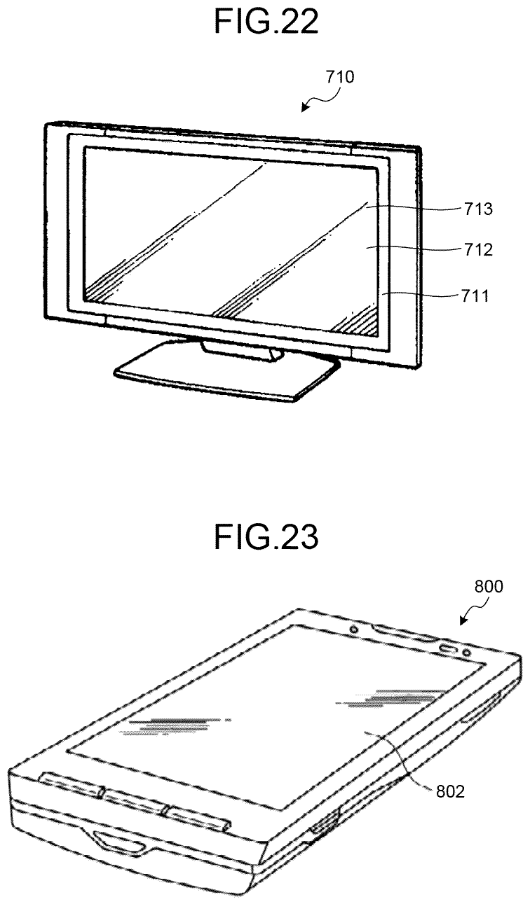

FIG. 22 illustrates an example of an external appearance of a television apparatus 710. The television apparatus 710 includes, for example, a video display screen unit 711 including a front panel 712 and a filter glass 713, and the video display screen unit 711 includes the display apparatus 10 according to an embodiment of the present disclosure.

### Specific Example 5

FIG. 23 illustrates an example of an external appearance of a smartphone 800. The smartphone 800 includes a display unit 802 that displays various types of information, and an operation unit including a button or the like that receives an operation input by the user. The display unit 802 can be the display apparatus 10 according to the present embodiment.

### Specific Example 6

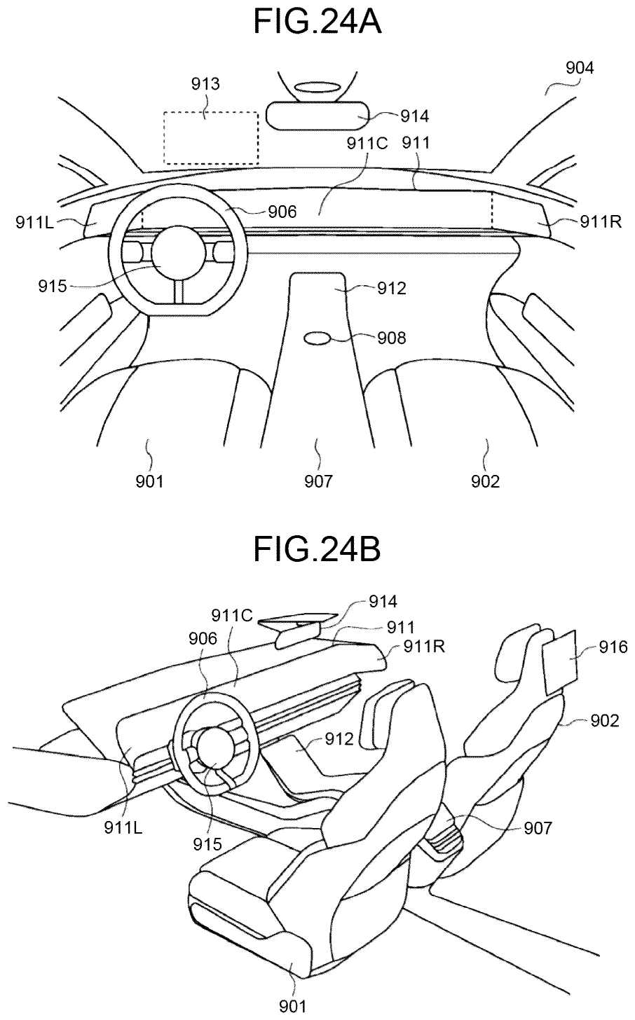

FIGS. 24A and 24B are diagrams illustrating an internal configuration of an automobile including the display apparatus 10 according to an embodiment of the present disclosure as a display apparatus. Specifically, FIG. 24A is a diagram illustrating a state of the inside of the automobile from the rear to the front of the automobile, and FIG. 24B is a diagram illustrating a state of the inside of the automobile from the oblique rear to the oblique front of the automobile.

The automobile illustrated in FIGS. 24A and 24B has a center display 911, a console display 912, a head-up display 913, a digital rear mirror 914, a steering wheel display 915, and a rear entertainment display 916. The display apparatus 10 according to an embodiment of the present disclosure can be applied to some or all of these displays.

The center display 911 is disposed on a center console 907 at a position facing a driver's seat 901 and a passenger seat 902. FIGS. 24A and 24B illustrate an example of the center display 911 having a horizontally long shape extending from the driver's seat 901 side to the passenger seat 902 side, but the screen size and the disposition place of the center display 911 can be freely selected. The center display 911 can display information detected by various sensors (not illustrated). As a specific example, the center display 911 can display a captured image captured by an image sensor, a distance image to an obstacle in front of or on a side of the automobile measured by a time of flight (ToF) sensor, a passenger's body temperature detected by an infrared sensor, and the like. The center display 911 can be used to display, for example, at least one piece of safety-related information, operation-related information, a life log, health-related information, authentication/identification-related information, and entertainment-related information.

The safety-related information is information such as doziness detection, looking-away detection, mischief detection of a child riding together, presence or absence of wearing of a seat belt, and detection of leaving of an occupant, and is information detected by, for example, a sensor (not illustrated) superimposed on the rear side of a center display 1911. The operation-related information detects a gesture related to the operation of an occupant using a sensor. The gesture to be detected may include operation of various types of equipment in the automobile. For example, operations of air conditioning equipment, a navigation device, an audio/visual (AV) device, a lighting device, and the like are detected. The life log includes a life log of all the occupants. For example, the life log includes an action record of each occupant in the automobile. Acquiring and storing the life log makes it possible to confirm the state of the occupant at the time of an accident. The health-related information detects the body temperature of an occupant using the temperature sensor, and estimates the health state of the occupant based on the detected body temperature. Alternatively, the face of the occupant may be imaged using an image sensor, and the health state of the occupant may be estimated from the imaged facial expression. Further, a conversation may be made with the occupant using an automatic voice, and the health condition of the occupant may be estimated based on the answer content of the occupant. The authentication/identification-related information includes a keyless entry function of performing face authentication using a sensor and an automatic adjustment function of a sheet height and a position with face identification. The entertainment-related information includes a function of detecting operation information of the AV device by the occupant using a sensor and a function of recognizing the face of the occupant by a sensor and providing content suitable for the occupant with the AV device.

The console display 912 can be used to display the life log information, for example. The console display 912 is disposed near a shift lever 908 of the center console 907 between the driver's seat 901 and the passenger seat 902. The console display 912 can also display information detected by various sensors (not illustrated). The console display 912 may display an image of the periphery of the vehicle captured by an image sensor, or may display a distance image to an obstacle in the periphery of the vehicle.

The head-up display 913 is virtually displayed behind a windshield 904 in front of the driver's seat 901. The head-up display 913 can be used to display, for example, at least one piece of safety-related information, operation-related information, a life log, health-related information, authentication/identification-related information, and entertainment-related information. Since the head-up display 913 is virtually disposed in front of the driver's seat 901 in many cases, the head-up display is suitable for displaying information directly related to the operation of the automobile such as the speed of the automobile and the remaining amount of fuel (battery).

The digital rear mirror 914 can display not only the rear of the automobile but also the state of the occupant in the back seat, and thus can be used to display the life log information, for example, by disposing a sensor (not illustrated) overlapping the rear surface side of the digital rear mirror 914.

The steering wheel display 915 is disposed near the center of a steering wheel 906 of the automobile. The steering wheel display 915 can be used to display, for example, at least one piece of safety-related information, operation-related information, a life log, health-related information, authentication/identification-related information, and entertainment-related information. In particular, since the steering wheel display 915 is close to the driver's hands, it is suitable for displaying life log information such as the body temperature of the driver, or for displaying information related to the operation of the AV device, air conditioning equipment, or the like.

The rear entertainment display 916 is attached to the rear side of the driver's seat 901 and the passenger seat 902, and is for viewing by an occupant in the rear seat. The rear entertainment display 916 can be used to display, for example, at least one piece of safety-related information, operation-related information, a life log, health-related information, authentication/identification-related information, and entertainment-related information. In particular, since the rear entertainment display 916 is in front of an occupant in the rear seat, information related to the occupant in the rear seat is displayed. For example, information regarding the operation of the AV device or the air conditioning equipment may be displayed, or a result of measuring the body temperature or the like of the occupant in the rear seat with a temperature sensor (not illustrated) may be displayed.

### 9. SUPPLEMENT

Although the preferred embodiments of the present disclosure have been described in detail with reference to the accompanying drawings, the technical scope of the present disclosure is not limited to such examples. It is obvious that a person having ordinary knowledge in the technical field of the present disclosure can conceive various changes or modifications within the scope of the technical idea described in the claims, and it is naturally understood that these also belong to the technical scope of the present disclosure.

The effects described in the present specification are merely illustrative or exemplary, and are not restrictive. That is, the technology according to the present disclosure can exhibit other effects obvious to those skilled in the art from the description of the present specification together with or instead of the above effects.

The present technology may also take the following configurations.

(1) A display apparatus comprising
a stack structure including:
a light-emitting element whose luminance changes according to a supplied current;
a current source transistor that is electrically connected to a current source and the light-emitting element and supplies a current corresponding to a signal voltage to the light-emitting element;
a capacitor connected to a control terminal of the current source transistor; and
a selection transistor that is connected to the control terminal of the current source transistor and supplies the signal voltage to the current source transistor via the capacitor, wherein
the stack structure includes:
a semiconductor substrate on which the current source transistor is provided;
a wiring layer stacked on the semiconductor substrate and including the capacitor and the selection transistor formed of a thin film transistor; and
the light-emitting element stacked on the wiring layer.
   (2) The display apparatus according to (1), wherein
in the wiring layer,
the capacitor is provided on the semiconductor substrate side, and
the selection transistor is provided above the capacitor.
   (3) The display apparatus according to (1), wherein
in the wiring layer,
the selection transistor is provided on the semiconductor substrate side, and
the capacitor is provided above the selection transistor.
   (4) The display apparatus according to any one of (1) to (3), wherein the selection transistor is an N-channel transistor.
   (5) The display apparatus according to any one of (1) to (4), wherein
the stack structure further includes
a switching transistor that is connected to the light-emitting element or the current source transistor and controls the light-emitting element not to emit light during a non-light-emitting period, and
the switching transistor is formed of the thin film transistor provided in the wiring layer.
   (6) The display apparatus according to (5), wherein the switching transistor is an N-channel transistor.
   (7) The display apparatus according to (5) or (6), wherein in the stack structure, a plurality of the thin film transistors are stacked along a stacking direction of the stack structure.
   (8) The display apparatus according to any one of (1) to (7), wherein the thin film transistor includes, as a channel, a thin film semiconductor layer containing at least one element selected from the group consisting of silicon, aluminum, indium, gallium, and zinc.
   (9) The display apparatus according to (8), in which the thin film semiconductor layer is formed of polysilicon or IGZO.
   (10) The display apparatus according to any one of (1) to (9), wherein in the stack structure, the thin film transistor has a top gate structure, a bottom gate structure, or a dual gate structure.
   (11) The display apparatus according to any one of (1) to (4), in which
the stack structure further includes
a switching transistor that is connected to the light-emitting element or the current source transistor and controls the light-emitting element not to emit light during a non-light-emitting period, and
the switching transistor is provided on the semiconductor substrate.
   (12) The display apparatus according to any one of (1) to (11), wherein the capacitor has an MIM structure formed of a pair of metal films sandwiching an insulating film from up and down directions along a stacking direction of the stack structure.
   (13) The display apparatus according to (12), wherein the insulating film is made of a silicon nitride film.
   (14) The display apparatus according to (12), wherein the insulating film is made of an oxide film containing at least one element selected from the group consisting of silicon, hafnium, zirconia, tantalum, and yttrium.
   (15) The display apparatus according to any one of (1) to (11), wherein the capacitor has an MIM structure formed of a metal film sandwiching an insulating film from planar directions perpendicular to a stacking direction of the stack structure.
   (16) The display apparatus according to any one of (1) to (15), wherein the current source transistor is a P-channel transistor.
   (17) The display apparatus according to any one of (1) to (15), wherein the current source transistor is an N-channel transistor.
   (18) The display apparatus according to any one of (1) to (17), wherein
the stack structure further includes
a light emission control transistor that is connected to the current source transistor and controls light emission of the light-emitting element, and
the light emission control transistor is provided on the semiconductor substrate.
   (19) The display apparatus according to (18), wherein
the current source transistor and the light emission control transistor have a series gate structure in which a source or a drain of one transistor and a source or a drain of the other transistor share one diffusion region.
   (20) The display apparatus according to any one of (1) to (17), in which
the stack structure further includes
a light emission control transistor that is connected to the current source transistor and controls light emission of the light-emitting element, and
the light emission control transistor is formed of the thin film transistor provided in the wiring layer.
   (21) The display apparatus according to (20), in which the light emission control transistor is an N-channel transistor.
   (22) The display apparatus according to any one of (1) to (21), wherein the semiconductor substrate has a butting contact structure in which a source contact of the current source transistor and a contact of a well region of the semiconductor substrate are electrically connected.
   (23) The display apparatus according to any one of (1) to (22), wherein the light-emitting element is an OLED.
   (24) An electronic device equipped with a display apparatus,
the display apparatus including
a stack structure including:
a light-emitting element whose luminance changes according to a supplied current;
a current source transistor that is electrically connected to a current source and the light-emitting element and supplies a current corresponding to a signal voltage to the light-emitting element;
a capacitor connected to a control terminal of the current source transistor; and
a selection transistor that is connected to the control terminal of the current source transistor and supplies the signal voltage to the current source transistor via the capacitor, wherein
the stack structure includes:
a semiconductor substrate on which the current source transistor is provided;
a wiring layer stacked on the semiconductor substrate and including the capacitor and the selection transistor formed of a thin film transistor; and
the light-emitting element stacked on the wiring layer.

### REFERENCE SIGNS LIST

10, 10a DISPLAY APPARATUS
20, 20a, 20b, 20c, 20d, 20e PIXEL
30 PIXEL ARRAY UNIT
31 SCAN LINE
32, 33 DRIVE LINE
34 SIGNAL LINE
40 WRITE SCAN UNIT
50, 60 DRIVE SCAN UNIT
70 SIGNAL OUTPUT UNIT
80 DISPLAY PANEL
100 SEMICONDUCTOR SUBSTRATE
102 DIFFUSION REGION
104, 104a, 224, 224a GATE ELECTRODE
106 SHALLOW TRENCH ISOLATION
200 WIRING LAYER
202, 214, 214a INSULATING FILM
204, 240, 242 WIRING LINE
206 VIA
210, 210a, 212, 310, 312 ELECTRODE
220, 220a THIN FILM SEMICONDUCTOR LAYER
230 NITRIDE FILM
260, 270, 272, 274, 276, 278, 280, 282, 284, 286, 288, 290, 292, 322, 324, 326 MASK
314 LIGHT-EMITTING LAYER
EL LIGHT-EMITTING ELEMENT
Tr1, Tr2, Tr2a, Tr2b, Tr3, Tr4, Tr4a, Tr4b TRANSISTOR
C1, C2, C3 CAPACITOR
V1, V2 CONTACT

1. A display apparatus comprising
a stack structure including:
a light-emitting element whose luminance changes according to a supplied current;
a current source transistor that is electrically connected to a current source and the light-emitting element and supplies a current corresponding to a signal voltage to the light-emitting element;
a capacitor connected to a control terminal of the current source transistor; and
a selection transistor that is connected to the control terminal of the current source transistor and supplies the signal voltage to the current source transistor via the capacitor, wherein
the stack structure includes:
a semiconductor substrate on which the current source transistor is provided;
a wiring layer stacked on the semiconductor substrate and including the capacitor and the selection transistor formed of a thin film transistor; and
the light-emitting element stacked on the wiring layer.

2. The display apparatus according to claim 1, wherein
in the wiring layer,
the capacitor is provided on the semiconductor substrate side, and
the selection transistor is provided above the capacitor.

3. The display apparatus according to claim 1, wherein
in the wiring layer,
the selection transistor is provided on the semiconductor substrate side, and
the capacitor is provided above the selection transistor.

4. The display apparatus according to claim 1, wherein the selection transistor is an N-channel transistor.

5. The display apparatus according to claim 1, wherein
the stack structure further includes
a switching transistor that is connected to the light-emitting element or the current source transistor and controls the light-emitting element not to emit light during a non-light-emitting period, and
the switching transistor is formed of the thin film transistor provided in the wiring layer.

6. The display apparatus according to claim 5, wherein the switching transistor is an N-channel transistor.

7. The display apparatus according to claim 5, wherein in the stack structure, a plurality of the thin film transistors are stacked along a stacking direction of the stack structure.

8. The display apparatus according to claim 1, wherein the thin film transistor includes, as a channel, a thin film semiconductor layer containing at least one element selected from the group consisting of silicon, aluminum, indium, gallium, and zinc.

9. The display apparatus according to claim 1, wherein in the stack structure, the thin film transistor has a top gate structure, a bottom gate structure, or a dual gate structure.

10. The display apparatus according to claim 1, wherein the capacitor has an MIM structure formed of a pair of metal films sandwiching an insulating film from up and down directions along a stacking direction of the stack structure.

11. The display apparatus according to claim 10, wherein the insulating film is made of a silicon nitride film.

12. The display apparatus according to claim 10, wherein the insulating film is made of an oxide film containing at least one element selected from the group consisting of silicon, hafnium, zirconia, tantalum, and yttrium.

13. The display apparatus according to claim 1, wherein the capacitor has an MIM structure formed of a metal film sandwiching an insulating film from planar directions perpendicular to a stacking direction of the stack structure.

14. The display apparatus according to claim 1, wherein the current source transistor is a P-channel transistor.

15. The display apparatus according to claim 1, wherein the current source transistor is an N-channel transistor.

16. The display apparatus according to claim 1, wherein
the stack structure further includes
a light emission control transistor that is connected to the current source transistor and controls light emission of the light-emitting element, and
the light emission control transistor is provided on the semiconductor substrate.

17. The display apparatus according to claim 16, wherein
the current source transistor and the light emission control transistor have a series gate structure in which a source or a drain of one transistor and a source or a drain of the other transistor share one diffusion region.

18. The display apparatus according to claim 1, wherein the semiconductor substrate has a butting contact structure in which a source contact of the current source transistor and a contact of a well region of the semiconductor substrate are electrically connected.

19. The display apparatus according to claim 1, wherein the light-emitting element is an OLED.

20. An electronic device equipped with a display apparatus,
the display apparatus including
a stack structure including:
a light-emitting element whose luminance changes according to a supplied current;
a current source transistor that is electrically connected to a current source and the light-emitting element and supplies a current corresponding to a signal voltage to the light-emitting element;
a capacitor connected to a control terminal of the current source transistor; and
a selection transistor that is connected to the control terminal of the current source transistor and supplies the signal voltage to the current source transistor via the capacitor, wherein
the stack structure includes:
a semiconductor substrate on which the current source transistor is provided;
a wiring layer stacked on the semiconductor substrate and including the capacitor and the selection transistor formed of a thin film transistor; and
the light-emitting element stacked on the wiring layer.
